(19) United States
(12) Patent Application Publication
(10) Pub. No.: US 2025/0119169 A1
(43) Pub. Date: Apr. 10, 2025

(54) RADIO FREQUENCY CIRCUIT

(71) Applicant: Murata Manufacturing Co., Ltd., Nagaokakyo-shi (JP)

(72) Inventors: Satoshi TANAKA, Nagaokakyo-shi (JP); Shinya HITOMI, Nagaokakyo-shi (JP); Hirotsugu MORI, Nagaokakyo-shi (JP)

(73) Assignee: Murata Manufacturing Co., Ltd., Nagaokakyo-shi (JP)

(21) Appl. No.: 18/983,463

(22) Filed: Dec. 17, 2024

Related U.S. Application Data
(63) Continuation of application No. PCT/JP2023/017295, filed on May 8, 2023.

(30) Foreign Application Priority Data
Jun. 21, 2022 (JP) 2022-099745

(51) Int. Cl. H04B 1/04; H03F 3/19; H04B 1/16

(52) U.S. Cl. CPC H04B 1/04; H03F 3/19; H04B 1/1607; H04B 2001/0408

(57) ABSTRACT

A radio frequency circuit supports a first power class and a second power class whose maximum output power is lower than that of the first power class, and includes: a first power amplifier; and a variable load matching circuit connected to an output end of the first power amplifier. Under a condition that the first power class is applied, a first power supply voltage is supplied to the first power amplifier, and a load impedance viewed from the first power amplifier is adjusted to a first impedance by the variable load matching circuit. Under a condition that the second power class is applied, a second power supply voltage is supplied to the first power amplifier, and the load impedance viewed from the first power amplifier is adjusted to a second impedance by the variable load matching circuit.

### CROSS-REFERENCE TO RELATED APPLICATIONS

This is a continuation application of PCT International Application No. PCT/JP2023/017295 filed on May 8, 2023, designating the United States of America, which is based on and claims priority to Japanese Patent Application No. 2022-099745 filed on Jun. 21, 2022. The entire disclosures of the above-identified applications, including the specifications, drawings, and claims are incorporated herein by reference in their entirety.

### TECHNICAL FIELD

The present disclosure relates to a radio frequency circuit.

### BACKGROUND

In mobile communication systems used in cellular phones, frequency bands for which radio station licenses are not necessary (hereinafter, referred to as unlicensed bands) have been actively used in addition to frequency bands for which radio station licenses are necessary (hereinafter, referred to as licensed bands). In licensed bands, power classes that allow higher maximum output powers (hereinafter, referred to as high-power classes) are used, whereas in unlicensed bands, power classes that are limited to lower maximum output powers (hereinafter, referred to as low-power classes) are used.

Japanese Unexamined Patent Application Publication No. 2017-17691 discloses a radio frequency circuit that can use unlicensed bands in addition to licensed bands.

### SUMMARY

### Technical Problems

However, as recognized by the present inventor, it is difficult for a power amplifier to support both the high-power and low-power classes with the above conventional technology.

In view of this, the present disclosure is to provide a radio frequency circuit that can support both high-power and low-power classes.

### Solutions

A radio frequency circuit according to an aspect of the present disclosure is a radio frequency circuit configured to support a first power class and a second power class whose maximum output power is lower than a maximum output power of the first power class, the radio frequency circuit including: a first power amplifier; and a variable load matching circuit connected to an output end of the first power amplifier. Under a condition that the first power class is applied, a first power supply voltage is supplied to the first power amplifier, and a load impedance viewed from the first power amplifier is adjusted to a first impedance by the variable load matching circuit. Under a condition that the second power class is applied, a second power supply voltage is supplied to the first power amplifier, and the load impedance viewed from the first power amplifier is adjusted to a second impedance by the variable load matching circuit. The first power supply voltage is higher than the second power supply voltage, and the first impedance is lower than the second impedance.

A radio frequency circuit according to an aspect of the present disclosure is a radio frequency circuit configured to support a first power class and a second power class whose maximum output power is lower than a maximum output power of the first power class, the radio frequency circuit including: a first power amplifier; a first filter; a second filter; and a switch circuit that includes a first terminal connected to an output end of the first power amplifier, a second terminal connected to the first filter, and a third terminal connected to the second filter. Under a condition that the first power class is applied, a first power supply voltage is supplied to the first power amplifier, and the first filter is connected to the first power amplifier by the switch circuit. Under a condition that the second power class is applied, a second power supply voltage is supplied to the first power amplifier, and the second filter is connected to the first power amplifier by the switch circuit. The first power supply voltage is higher than the second power supply voltage, and an input impedance of the first filter is lower than an input impedance of the second filter. Additional benefits and advantages of the disclosed embodiments will be apparent from the Specification and the drawings. The benefits and/or advantages may be individually obtained by various embodiments and features of the Specification and the drawings, all of which need not be provided in order to obtain one or more of the benefits and/or advantages.

### Advantageous Effects

According to a radio frequency circuit according to the present disclosure, both high-power and low-power classes can be supported.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates a circuit configuration of a communication device according to Embodiment 1.

FIG. 2 illustrates a circuit configuration of an example of a variable load matching circuit according to Embodiment 1.

FIG. 3 illustrates a circuit configuration of another example of a variable load matching circuit according to Embodiment 1.

FIG. 4 illustrates a circuit configuration of a communication device according to Embodiment 2.

FIG. 5 illustrates a circuit configuration of an example of a variable load matching circuit according to Embodiment 2.

FIG. 6 illustrates a circuit configuration of another example of a variable load matching circuit according to Embodiment 2.

FIG. 7 illustrates a circuit configuration of a communication device according to Embodiment 3.

FIG. 8 illustrates a circuit configuration of a variable load matching circuit according to Embodiment 3.

FIG. 9 illustrates a circuit configuration of a communication device according to Embodiment 4.

FIG. 10 illustrates a circuit configuration of a communication device according to Embodiment 5.

FIG. 11 illustrates a circuit configuration of a communication device according to Embodiment 6.

FIG. 12 illustrates a circuit configuration of a communication device according to Embodiment 7.

FIG. 13 illustrates a circuit configuration of a communication device according to Embodiment 8.

FIG. 14 illustrates a circuit configuration of a communication device according to Embodiment 9.

FIG. 15 illustrates a circuit configuration of a communication device according to Embodiment 10.

FIG. 16 illustrates a circuit configuration of a communication device according to another embodiment.

### DESCRIPTION OF EMBODIMENTS

The following describes in detail embodiments of the present disclosure. Note that the embodiments described below each show a general or specific example. The numerical values, shapes, materials, elements, and the arrangement and connection of the elements, for instance, described in the following embodiments are examples, and thus are not intended to limit the present disclosure.

Note that the drawings are schematic diagrams to which emphasis, omission and ratio adjustment are appropriately added in order to illustrate the present disclosure, and thus are not necessarily accurate illustrations. The drawings may show shapes, positional relations, and ratios that are different from actual shapes, actual positional relations, and actual ratios. Throughout the drawings, the same numeral is given to substantially the same element, and redundant description may be omitted or simplified.

In the circuit configurations according to the present disclosure, “being connected” includes not only the case of being directly connected by a connection terminal and/or a line conductor, but also the case of being electrically connected via another circuit element. “Being connected between A and B” means being connected between A and B and to both A and B, and means being disposed in series onto a path that connects A and B.

In the circuit configurations according to the present disclosure, a “terminal” means a point at which a conductor in an element ends. Note that under a condition that an impedance of a path between elements is sufficiently low, a terminal is interpreted not only as a single fixed point, but as any point on the path between the elements or as the entire path.

### Embodiment 1

Embodiment 1 is to be described. Communication device 6 according to the present embodiment corresponds to a user equipment (UE) in a cellular network, and typically is a mobile phone, a smartphone, a tablet computer, or a wearable device, for instance. Note that communication device 6 may be an Internet of Things (IoT) sensor/device, a medical/health care device, a vehicle, an unmanned aerial vehicle (UAV) (a so-called drone), or an automated guided vehicle (AGV).

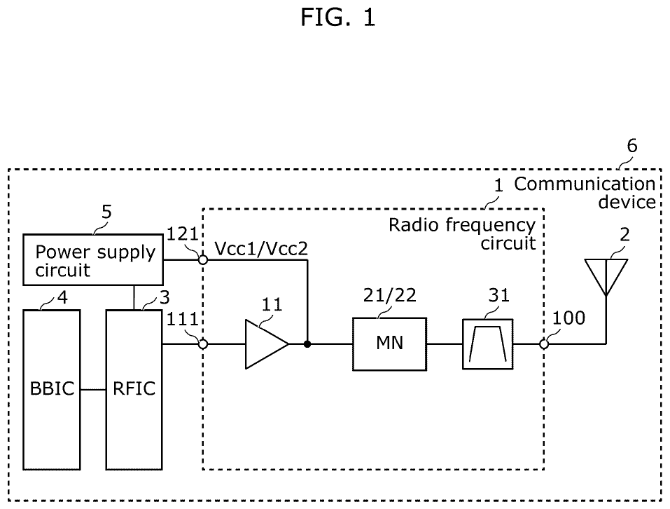

A circuit configuration of communication device 6 and radio frequency circuit 1 according to the present embodiment is to be described with reference to FIG. 1. FIG. 1 illustrates a circuit configuration of communication device 6 according to the present embodiment.

Note that FIG. 1 illustrates an exemplary circuit configuration, and communication device 6 and radio frequency circuit 1 may be implemented using any of various types of circuit implementations and circuit technologies. Thus, the description of communication device 6 and radio frequency circuit 1 provided below should not be interpreted in a limited manner.

### 1.1 Circuit Configuration of Communication Device 6

First, communication device 6 according to the present embodiment is to be described with reference to FIG. 1. Communication device 6 includes radio frequency circuit 1, antenna 2, radio frequency integrated circuit (RFIC) 3, baseband integrated circuit (BBIC) 4, and power supply circuit 5.

Radio frequency circuit 1 transfers radio frequency signals between antenna 2 and RFIC 3. A circuit configuration of radio frequency circuit 1 is to be described later.

Antenna 2 is connected to antenna connection terminal 100 of radio frequency circuit 1. Antenna 2 receives radio frequency signals from radio frequency circuit 1 and outputs the radio frequency signals to the outside of communication device 6. Antenna 2 may receive radio frequency signals from the outside of communication device 6 and output the radio frequency signals to radio frequency circuit 1. Note that antenna 2 may not be included in communication device 6. Communication device 6 may further include one or more antennas in addition to antenna 2.

RFIC 3 is an example of a signal processing circuit that processes radio frequency signals. Specifically, RFIC 3 processes, by, for instance, up-conversion, transmission signals input from BBIC 4 and outputs radio frequency transmission signals generated by processing the transmission signals to radio frequency circuit 1. RFIC 3 includes a controller that controls, for instance, a switch and an amplifier circuit that are included in radio frequency circuit 1 and/or power supply circuit 5. Note that part of or the entire functionality of RFIC 3 as a controller may be provided outside of RFIC 3, and thus may be provided in BBIC 4, radio frequency circuit 1, or power supply circuit 5, for example.

BBIC 4 is a base band signal processing circuit that processes signals using an intermediate frequency band lower than frequencies of radio frequency signals transferred by radio frequency circuit 1. The signals processed by BBIC 4 are used, for example, as image signals for image display and/or as audio signals for talk through a loudspeaker. Note that BBIC 4 may not be included in communication device 6.

Power supply circuit 5 is configured to supply a power supply voltage to radio frequency circuit 1. At this time, power supply circuit 5 can selectively supply power supply voltages Vcc1 and Vcc2 of at least two levels. Power supply voltage Vcc1 is an example of a first power supply voltage and is higher than power supply voltage Vcc2. Power supply voltage Vcc2 is an example of a second power supply voltage and is lower than power supply voltage Vcc1. A 6-volt voltage level, for example, is used as power supply voltage Vcc1, whereas a 3-volt voltage level, for example, is used as power supply voltage Vcc2.

### 1.2 Circuit Configuration of Radio Frequency Circuit 1

Next, radio frequency circuit 1 according to the present embodiment is to be described with reference to FIG. 1. Radio frequency circuit 1 includes power amplifier 11, variable load matching circuit 21 or 22, filter 31, antenna connection terminal 100, input terminal 111, and power supply voltage terminal 121.

Antenna connection terminal 100 is an external connection terminal of radio frequency circuit 1, and is for supplying transmission signals to the outside of radio frequency circuit 1. Antenna connection terminal 100 is connected to antenna 2 outside radio frequency circuit 1 and is connected to filter 31 inside radio frequency circuit 1.

Input terminal 111 is an external connection terminal of radio frequency circuit 1, and is for receiving transmission signals from the outside of radio frequency circuit 1. Input terminal 111 is connected to RFIC 3 outside radio frequency circuit 1 and is connected to power amplifier 11 inside radio frequency circuit 1. Accordingly, the transmission signals received from RFIC 3 via input terminal 111 are supplied to power amplifier 11.

Power supply voltage terminal 121 is an external connection terminal of radio frequency circuit 1 and is for receiving power supply voltages Vcc1 and Vcc2 from power supply circuit 5. Power supply voltage terminal 121 is connected to power supply circuit 5 outside radio frequency circuit 1 and is connected to power amplifier 11 inside radio frequency circuit 1. Accordingly, power supply voltages Vcc1 and Vcc2 received from power supply circuit 5 via power supply voltage terminal 121 are supplied to power amplifier 11.

Power amplifier 11 is an example of a first power amplifier. An input end of power amplifier 11 is connected to input terminal 111. An output end of power amplifier 11 is connected to variable load matching circuit 21 or 22. Furthermore, power amplifier 11 is connected to power supply voltage terminal 121.

With this connection configuration, power amplifier 11 can amplify radio frequency signals supplied from RFIC 3 via input end 111, by using power supply voltages Vcc1 and Vcc2 supplied from power supply circuit 5 via power supply voltage terminal 121.

Such power amplifier 11 can include a heterojunction bipolar transistor (HBT) and can be manufactured using a semiconductor material. As the semiconductor material, silicon-germanium (SiGe) or gallium arsenide (GaAs) can be used, for example. Note that the amplifier transistor in power amplifier 11 is not limited to an HBT. For example, power amplifier 11 may include a high electron mobility transistor (HEMT) or a metal-semiconductor field effect transistor (MESFET). In this case, gallium nitride (GaN) or silicon carbide (SiC) may be used as the semiconductor material.

Note that power amplifier 11 can support a first power class, a second power class, and a third power class. Under a condition that the first power class is applied, power supply voltage Vcc1 is supplied to power amplifier 11, whereas under a condition that the second power class and the third power class are applied, power supply voltage Vcc2 is supplied to power amplifier 11. Note that power amplifier 11 may not be able to support the third power class.

The maximum output power of the first power class is higher than the maximum output power of the second power class and the maximum output power of the third power class, and the first power class corresponds to a high-power class. The maximum output power of the second power class is lower than the maximum output power of the first power class and the maximum output power of the third power class, and the second power class corresponds to a low-power class. The maximum output power of the third power class is lower than the maximum output power of the first power class and higher than the maximum output power of the second power class, and the third power class corresponds to a middle-power class.

Note that the power classes are classifications of output powers of terminals defined by maximum output powers, and the smaller the value of the power class is, the higher output power is permitted. For example, according to the 3rd Generation Partnership Project (3GPP (registered trademark), the maximum output power of power class 1 is 31 dBm, the maximum output power of power class 1.5 is 29 dBm, the maximum output power of power class 2 is 26 dBm, the maximum output power of power class 3 is 23 dBm, and the maximum output power of power class 5 is 20 dBm.

The maximum output power of a terminal device is defined by the maximum output power of an antenna terminal of the terminal device. The maximum output power of a terminal device is measured by using a method defined by the 3GPP, for instance. In FIG. 1, the maximum output power is measured by measuring radiant power of antenna 2, for example. Note that instead of measuring radiant power, the maximum output power of antenna 2 can be measured by providing a terminal in the vicinity of antenna 2 and connecting a measuring instrument (a spectrum analyzer, for example) to the terminal.

The power class supported by a power amplifier can be identified by the maximum output power of the power amplifier. For example, the maximum output power of a power amplifier that supports power class 2 is higher than 26 dBm.

In the present embodiment, power class 2 is used as the first power class, power class 5 is used as the second power class, and power class 3 is used as the third power class. Note that combinations of the first power class, the second power class, and the third power class are not limited to these. For example, power class 1.5 may be used as the first power class, power class 3 may be used as the second power class, and power class 2 may be used as the third power class.

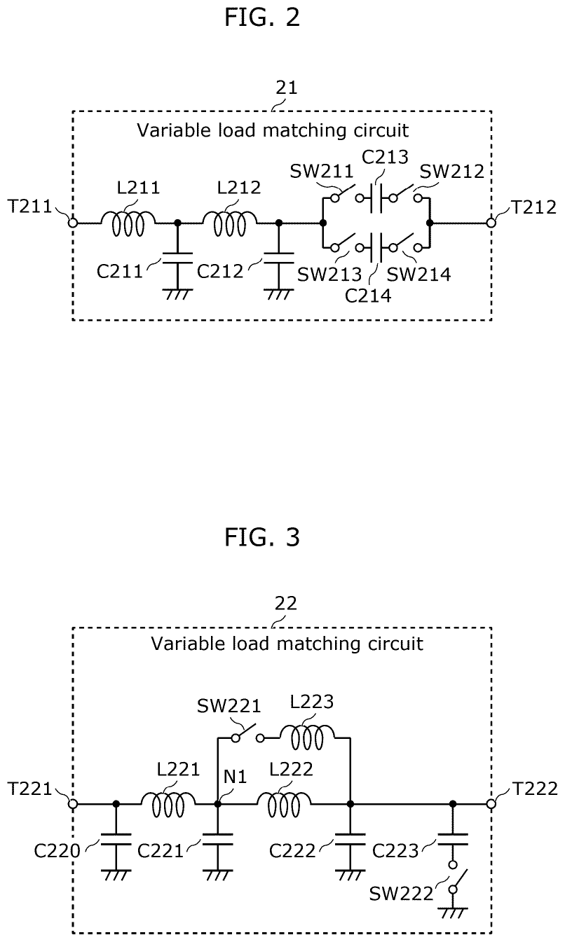

Variable load matching circuits 21 and 22 are variable impedance matching circuits configured to adjust a load impedance viewed from power amplifier 11 according to a power class. Radio frequency circuit 1 includes one of variable load matching circuit 21 or 22. Note that circuit configurations of variable load matching circuits 21 and 22 are to be described later with reference to FIG. 2 and FIG. 3.

Filter 31 is connected between antenna connection terminal 100 and variable load matching circuit 21 or 22. Specifically, one end of filter 31 is connected to variable load matching circuit 21 or 22, and another end of filter 31 is connected to antenna connection terminal 100. Filter 31 supports a predetermined band and is a band pass filter having a passband that includes the predetermined band. Filter 31 has power durability for the first power class. For example, 5150 MHz to 7125 MHz, 5925 MHz to 7125 MHz, or 6425 MHz to 7125 MHz can be used as the passband of filter 31, but the passband of filter 31 is not limited to these. A surface acoustic wave (SAW) filter, a bulk acoustic wave (BAW) filter, an inductor-capacitor (LC) resonator filter, a dielectric resonator filter, or a combination of any of these may be used as filter 31, and furthermore, filter 31 is not limited to these. Note that filter 31 may not be included in radio frequency circuit 1.

The predetermined band is a frequency band for a communication system established by using radio access technology (RAT). The predetermined band is defined in advance by, for instance, a standardizing body (such as the 3GPP or the Institute of Electrical and Electronics Engineers (IEEE), for example). Examples of a communication system include a 5th Generation New Radio (5G NR) system, a Long Term Evolution (LTE) system, and a Wireless Local Area Network (WLAN) system. For example, n46, n96, n102, or n104 or any combination of these can be used as the predetermined band, but the predetermined band is not limited thereto.

### 1.3 Circuit Configuration of Variable Load Matching Circuit

Here, variable load matching circuits 21 and 22 are to be described sequentially as different examples of a variable load matching circuit according to the present embodiment.

### [1.3.1 Circuit Configuration of Variable Load Matching Circuit 21]

First, a circuit configuration of variable load matching circuit 21 that is an example of the variable load matching circuit according to the present embodiment is to be described with reference to FIG. 2. FIG. 2 illustrates a circuit configuration of variable load matching circuit 21 according to the present embodiment.

Note that FIG. 2 illustrates an exemplary circuit configuration, and variable load matching circuit 21 may be implemented using any of various types of circuit implementations and circuit technologies. Thus, the description of variable load matching circuit 21 provided below should not be interpreted in a limited manner.

Variable load matching circuit 21 includes inductors L211 and L212, capacitors C211 to C214, switches SW211 to SW214, input terminal T211, and output terminal T212.

Input terminal T211 is connected to the output end of power amplifier 11 outside variable load matching circuit 21 and is connected to inductor L211 inside variable load matching circuit 21. Output terminal T212 is connected to antenna connection terminal 100 via filter 31 outside variable load matching circuit 21, and is connected to capacitors C213 and C214 inside variable load matching circuit 21.

Inductors L211 and L212, switch SW211, capacitor C213, and switch SW212 are connected in series between input terminal T211 and output terminal T212. Furthermore, switch SW213, capacitor C214, and switch SW214 are connected in series between inductor L212 and output terminal T212, and connected in parallel to switch SW211, capacitor C213, and switch SW212.

Capacitors C211 and C212 are connected in parallel to each other, between the ground and a path between input terminal T211 and output terminal T212. Specifically, capacitor C211 is connected between the ground and a path between inductors L211 and L212. Capacitor C212 is connected between the ground and a path between inductor L212 and capacitors C213 and C214.

Switches SW211 and SW212 are examples of a first switch and each include a single-pole single-throw (SPST) switch circuit. One end of switch SW211 is connected to inductor L212. Another end of switch SW211 is connected to capacitor C213. One end of switch SW212 is connected to capacitor C213. Another end of switch SW212 is connected to output terminal T212. Note that one of switch SW211 or switch SW212 may not be included in variable load matching circuit 21.

Capacitor C213 is an example of a first capacitor. One end of capacitor C213 is connected to switch SW211. Another end of capacitor C213 is connected to switch SW212.

Switches SW213 and SW214 are examples of a second switch and each include an SPST switch circuit. One end of switch SW213 is connected to inductor L212, and another end of switch SW213 is connected to capacitor C214. One end of switch SW214 is connected to capacitor C214, and another end of switch SW214 is connected to output terminal T212. Note that one of switch SW213 or switch SW214 may not be included in variable load matching circuit 21.

Capacitor C214 is an example of a second capacitor. One end of capacitor C214 is connected to switch SW213. Another end of capacitor C214 is connected to switch SW214.

With such a connection configuration, switches SW211 and SW212 are closed (or stated differently, turned on) under a condition that the first power class and the third power class are applied, and are open (or stated differently, turned off) under a condition that the second power class is applied. On the other hand, switches SW213 and SW214 are open under the condition that the first power class and the third power class are applied, and are closed under the condition that the second power class is applied. Stated differently, capacitor C213 is selected under the condition that the first power class and the third power class is applied, and capacitor C214 is selected under the condition that the second power class is applied.

The capacitance of capacitor C214 is smaller than the capacitance of capacitor C213. Conversely, the capacitance of capacitor C213 is larger than the capacitance of capacitor C214. Accordingly, the load impedance viewed from power amplifier 11 is adjusted to a lower first impedance (3 ohm, for example) under the condition that the first power class and the third power class are applied, and is adjusted to a higher second impedance (6 ohm, for example) under the condition that the second power class is applied.

Note that the capacitances of capacitors C213 and C214 can be measured by using an LCR meter. At this time, the automatic balance bridge method can be used as a measuring method. The load impedance viewed from power amplifier 11 can be identified by measuring an impedance at a center frequency of a predetermined band by using a network analyzer.

### [1.3.2 Circuit Configuration of Variable Load Matching Circuit 22]

Next, a circuit configuration of variable load matching circuit 22 that is another example of the variable load matching circuit according to the present embodiment is to be described with reference to FIG. 3. FIG. 3 illustrates a circuit configuration of variable load matching circuit 22 according to the present embodiment.

Note that FIG. 3 illustrates an exemplary circuit configuration, and variable load matching circuit 22 may be implemented using any of various types of circuit implementations and circuit technologies. Thus, the description of variable load matching circuit 22 provided below should not be interpreted in a limited manner.

Variable load matching circuit 22 includes inductors L221 and L223, capacitors C220 to C223, switches SW221 and SW222, input terminal T221, and output terminal T222.

Input terminal T221 is connected to the output end of power amplifier 11 outside variable load matching circuit 22 and is connected to inductor L221 inside variable load matching circuit 22. Output terminal T222 is connected to antenna connection terminal 100 via filter 31 outside variable load matching circuit 22, and is connected to inductors L222 and L223 inside variable load matching circuit 22.

Inductors L221 and L222 are connected in series between input terminal T221 and output terminal T222. Here, inductor L222 is an example of a first inductor. Furthermore, switch SW221 and inductor L223 are an example of a first switch and an example of a second inductor, respectively, are connected in series between inductor L221 and output terminal T222, and are connected in parallel to inductor L222.

Capacitors C220 to C223 are connected in parallel to one another, between the ground and a path between input terminal T221 and output terminal T222. Specifically, capacitor C220 is connected between the ground and a path between input terminal T221 and inductor L221. Capacitor C221 is connected between the ground and a path between inductors L221 and L222. Capacitor C222 is an example of a first capacitor, and is connected between the ground and a path between inductor L222 and output terminal T222. Capacitor C223 and switch SW222 are an example of a second capacitor and an example of a second switch, respectively. Capacitor C223 and switch SW222 are connected in series between the ground and the path between inductor L222 and output terminal T222, and are connected in parallel to capacitor C222.

With such a connection configuration, switch SW221 is open under a condition that the first power class and the third power class are applied and is closed under a condition that the second power class is applied. On the other hand, switch SW222 is open under the condition that the first power class and the third power class are applied and is closed under the condition that the second power class is applied. Stated differently, under the condition that the first power class and the third power class are applied, at least one end of inductor L223 is not connected to the path between input terminal T221 and output terminal T222, and one of two ends of capacitor C223 is connected to the path between input terminal T221 and output terminal T222, and the remaining one thereof is connected to the ground. On the other hand, under the condition that the second power class is applied, two ends of inductor L223 are connected to the path between input terminal T221 and output terminal T222, and at least one end of capacitor C223 is not connected to the path between input terminal T221 and output terminal T222 or to the ground.

Accordingly, a load impedance viewed from node N1 is higher under the condition that the first power class and the third power class are applied and is lower under the condition that the second power class is applied. At this time, a pi matching circuit that includes capacitors C220 and C221 and inductor L221 functions as an impedance inverter. Thus, a load impedance viewed from input terminal T221 is lower under the condition that the first power class and the third power class are applied and is higher under the condition that the second power class is applied. As a result, the load impedance viewed from power amplifier 11 is adjusted to a lower first impedance (3 ohm, for example) under the condition that the first power class and the third power class are applied, and is adjusted to a higher second impedance (6 ohm, for example) under the condition that the second power class is applied.

### 1.4 Advantageous Effects and Others

As described above, radio frequency circuit 1 according to the present embodiment is radio frequency circuit 1 configured to support a first power class and a second power class whose maximum output power is lower than a maximum output power of the first power class, radio frequency circuit 1 including: power amplifier 11; and variable load matching circuit 21 or 22 connected to an output end of power amplifier 11. Under a condition that the first power class is applied, power supply voltage Vcc1 is supplied to power amplifier 11, and a load impedance viewed from power amplifier 11 is adjusted to a first impedance by variable load matching circuit 21 or 22. Under a condition that the second power class is applied, power supply voltage Vcc2 is supplied to power amplifier 11, and the load impedance viewed from power amplifier 11 is adjusted to a second impedance by variable load matching circuit 21 or 22. Power supply voltage Vcc1 is higher than power supply voltage Vcc2, and the first impedance is lower than the second impedance.

According to this, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1 according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and the load impedance viewed from power amplifier 11 may be adjusted to the first impedance by variable load matching circuit 21 or 22.

According to this, in the third power class between the first power class and the second power class, the same power supply voltage as in the second power class is supplied, and the load impedance is adjusted to the same load impedance as in the first power class. Thus, power efficiency can be improved by reducing an increase in power supply voltage in the third power class.

For example, in radio frequency circuit 1 according to the present embodiment, variable load matching circuit 21 may include: capacitor C213 and switch SW211 and/or switch SW212 connected in series between power amplifier 11 and antenna connection terminal 100; and capacitor C214 and switch SW213 and/or switch SW214 connected in parallel to capacitor C213 and switch SW211 and/or switch SW212, between power amplifier 11 and antenna connection terminal 100, capacitor C214 and switch SW213 and/or switch SW214 being connected in series, a capacitance of capacitor C213 may be greater than a capacitance of capacitor C214, under the condition that the first power class is applied, switch SW211 and/or switch SW212 may be closed, and switch SW213 and/or switch SW214 may be open, and under the condition that the second power class is applied, switch SW211 and/or switch SW212 may be open, and switch SW213 and/or switch SW214 may be closed.

According to this, the load impedance viewed from power amplifier 11 can be adjusted to the first impedance or the second impedance by switching between capacitors C213 and C214 on the signal path.

For example, in radio frequency circuit 1 according to the present embodiment, variable load matching circuit 22 may include: inductor L222 connected between power amplifier 11 and antenna connection terminal 100; inductor L223 and switch SW221 connected in parallel to inductor L222, between power amplifier 11 and antenna connection terminal 100, inductor L223 and switch SW221 being connected in series; capacitor C222 connected between ground and a path between power amplifier 11 and antenna connection terminal 100; and capacitor C223 and switch SW222 connected in parallel to capacitor C222, between the ground and the path between power amplifier 11 and antenna connection terminal 100, capacitor C223 and switch SW222 being connected in series, under the condition that the first power class is applied, switch SW221 may be open, and switch SW222 may be closed, and under the condition that the second power class is applied, switch SW221 may be closed, and switch SW222 may be open.

According to this, in the second power class, the load impedance viewed from power amplifier 11 can be adjusted to the second impedance by connecting inductor L222 on the signal path in parallel to inductor L223 and connecting capacitor C223 between the signal path and the ground. In particular, switch SW221 on the signal path is not closed in the first power class, and thus a signal loss due to switch SW221 can be reduced.

### Embodiment 2

Next, Embodiment 2 is to be described. The present embodiment is different from Embodiment 1 above mainly in that a differential-amplifier type amplifier circuit is used as a power amplifier circuit. In the following, the present embodiment is to be described with reference to the drawings, focusing on different points from Embodiment 1 above.

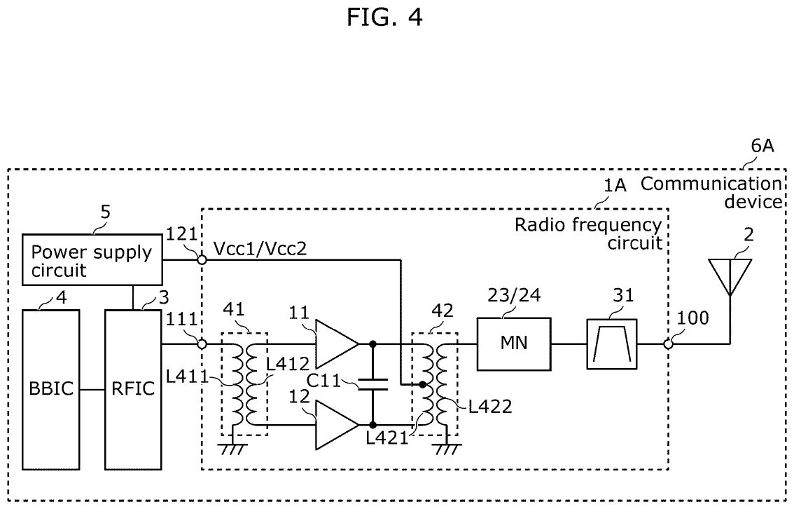

A circuit configuration of communication device 6A and radio frequency circuit 1A according to the present embodiment is to be described with reference to FIG. 4. FIG. 4 illustrates a circuit configuration of communication device 6A according to the present embodiment.

Note that FIG. 4 illustrates an exemplary circuit configuration, and communication device 6A and radio frequency circuit 1A may be implemented using any of various types of circuit implementations and circuit technologies. Thus, the description of communication device 6A and radio frequency circuit 1A provided below should not be interpreted in a limited manner.

Communication device 6A is the same as communication device 6, except that radio frequency circuit 1A is included instead of radio frequency circuit 1, and thus a description thereof is omitted.

### 2.1 Circuit Configuration of Radio Frequency Circuit 1A

Radio frequency circuit 1A according to the present embodiment is to be described with reference to FIG. 4. Radio frequency circuit 1A includes power amplifiers 11 and 12, variable load matching circuit 23 or 24, filter 31, transformers 41 and 42, capacitor C11, antenna connection terminal 100, input terminal 111, and power supply voltage terminal 121.

Power amplifier 11 is an example of a first power amplifier. The input end of power amplifier 11 is connected to transformer 41. The output end of power amplifier 11 is connected to transformer 42. Power amplifier 11 can amplify one of differential signals output from transformer 41.

Power amplifier 12 is an example of a second power amplifier. The input end of power amplifier 12 is connected to transformer 41. The output end of power amplifier 12 is connected to transformer 42. Power amplifier 12 can amplify the other of differential signals output from transformer 41.

Such power amplifier 12 can include an HBT, and can be manufactured using a semiconductor material. As the semiconductor material, SiGe or GaAs can be used, for example, but the semiconductor material is not limited thereto.

Power amplifiers 11 and 12 can support a first power class, a second power class, and a third power class. Under a condition that the first power class is applied, power supply voltage Vcc1 is supplied to power amplifiers 11 and 12, whereas under a condition that the second power class and the third power class are applied, power supply voltage Vcc2 is supplied to power amplifiers 11 and 12. Note that power amplifiers 11 and 12 may not be able to support the third power class.

Transformer 41 includes primary coil L411 and secondary coil L412 coupled to primary coil L411. One end of primary coil L411 is connected to input terminal 111, and another end of primary coil L411 is connected to the ground. Two ends of secondary coil L412 are connected to the input ends of power amplifiers 11 and 12.

With this connection configuration, transformer 41 can divide a radio frequency signal supplied from RFIC 3 via input terminal 111 into two antiphase radio frequency signals. The divided two radio frequency signals (that is, differential signals) are supplied to power amplifiers 11 and 12.

Note that transformer 41 may not be included in radio frequency circuit 1A. In this case, radio frequency circuit 1A may include two input terminals 111 for receiving differential signals from RFIC 3, for example.

Transformer 42 includes primary coil L421 and secondary coil L422 coupled to primary coil L421. Two ends of primary coil L421 are connected to the output ends of power amplifiers 11 and 12. Primary coil L421 is divided into two coils, and power supply voltage terminal 121 is connected to a node between the two coils. One end of secondary coil L422 is connected to variable load matching circuit 23 or 24. Another end of secondary coil L422 is connected to the ground.

With this connection configuration, transformer 42 can combine differential signals amplified by power amplifiers 11 and 12 into one radio frequency signal. The combined radio frequency signal is transferred to antenna connection terminal 100 via variable load matching circuit 23 or 24 and filter 31.

Capacitor C11 is connected between the output end of power amplifier 11 and the output end of power amplifier 12, in parallel to primary coil L421 of transformer 42. Specifically, one end of capacitor C11 is connected to the output end of power amplifier 11 and one end of primary coil L421, and another end of capacitor C11 is connected to the output end of power amplifier 12 and another end of primary coil L421.

Variable load matching circuits 23 and 24 are variable impedance matching circuits configured to adjust a load impedance viewed from power amplifiers 11 and 12 according to a power class. Radio frequency circuit 1A includes one of variable load matching circuit 23 or 24.

### 2.2 Circuit Configuration of Variable Load Matching Circuit

Here, variable load matching circuits 23 and 24 are to be described sequentially as different examples of the variable load matching circuit according to the present embodiment.

### [2.2.1 Circuit Configuration of Variable Load Matching Circuit 23]

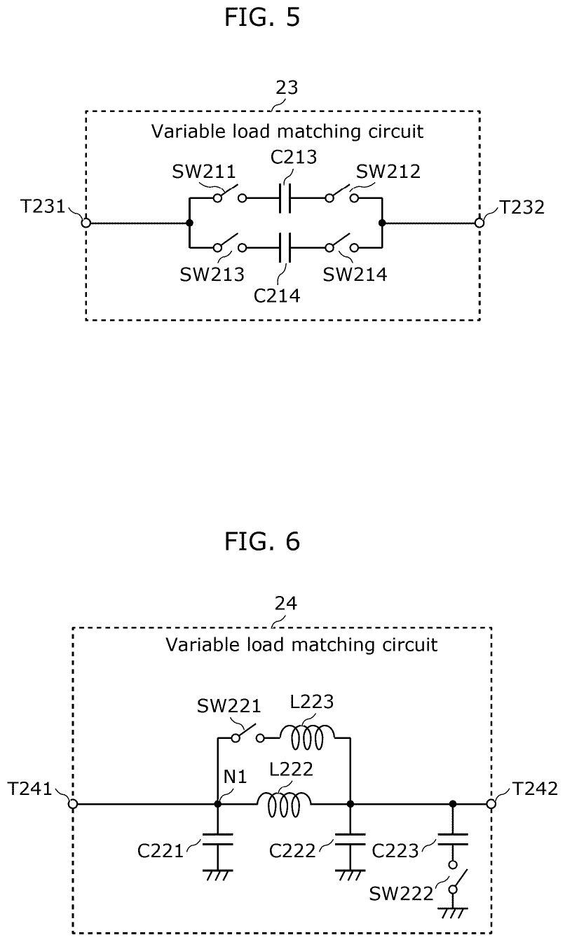

First, a circuit configuration of variable load matching circuit 23 that is an example of the variable load matching circuit according to the present embodiment is to be described with reference to FIG. 5. FIG. 5 illustrates a circuit configuration of variable load matching circuit 23 according to the present embodiment.

Note that FIG. 5 illustrates an exemplary circuit configuration, and variable load matching circuit 23 may be implemented using any of various types of circuit implementations and circuit technologies. Thus, the description of variable load matching circuit 23 provided below should not be interpreted in a limited manner.

Variable load matching circuit 23 includes capacitors C213 and C214, switches SW211 to SW214, input terminal T231, and output terminal T232. Variable load matching circuit 23 corresponds to a circuit resulting from removing inductors L211 and L212 and capacitors C211 and C212 from variable load matching circuit 21 according to Embodiment 1 and replacing input terminal T211 and output terminal T212 in variable load matching circuit 21 with input terminal T231 and output terminal T232.

Input terminal T231 is connected to secondary coil L422 of transformer 42 outside variable load matching circuit 23, and is connected to capacitors C213 and C214 inside variable load matching circuit 23. Output terminal T232 is connected to antenna connection terminal 100 via filter 31 outside variable load matching circuit 23, and is connected to capacitors C213 and C214 inside variable load matching circuit 23.

Similarly to variable load matching circuit 21 according to Embodiment 1, switches SW211 and SW212 are closed under a condition that the first power class and the third power class are applied and is open under a condition that the second power class is applied. On the other hand, switches SW213 and SW214 are open under the condition that the first power class and the third power class are applied and is closed under the condition that the second power class is applied. Stated differently, capacitor C213 is selected under the condition that the first power class and the third power class are applied, and capacitor C214 is selected under the condition that the second power class is applied.

Since the capacitance of capacitor C213 is greater than the capacitance of capacitor C214, the load impedance viewed from power amplifiers 11 and 12 is adjusted to a lower first impedance (3 ohm, for example) under the condition that the first power class and the third power class are applied, and is adjusted to a higher second impedance (6 ohm, for example) under the condition that the second power class is applied.

### [2.2.2 Circuit Configuration of Variable Load Matching Circuit 24]

Next, a circuit configuration of variable load matching circuit 24 that is another example of the variable load matching circuit according to the present embodiment is to be described with reference to FIG. 6. FIG. 6 illustrates a circuit configuration of variable load matching circuit 24 according to the present embodiment.

Note that FIG. 6 illustrates an exemplary circuit configuration, and variable load matching circuit 24 may be implemented using any of various types of circuit implementations and circuit technologies. Thus, the description of variable load matching circuit 24 provided below should not be interpreted in a limited manner.

Variable load matching circuit 24 includes inductors L222 and L223, capacitors C221 to C223, switches SW221 and SW222, input terminal T241, and output terminal T242. Variable load matching circuit 24 corresponds to a circuit resulting from removing inductor L221 and capacitor C220 from variable load matching circuit 22 according to Embodiment 1 and replacing input terminal T221 and output terminal T222 in variable load matching circuit 22 with input terminal T241 and output terminal T242.

Input terminal T241 is connected to secondary coil L422 of transformer 42 outside variable load matching circuit 24, and is connected to inductors L222 and L223 inside variable load matching circuit 24. Output terminal T242 is connected to antenna connection terminal 100 via filter 31 outside variable load matching circuit 24, and is connected to inductors L222 and L223 inside variable load matching circuit 24.

Similarly to variable load matching circuit 22 according to Embodiment 1, switch SW221 is open under a condition that the first power class and the third power class are applied and is closed under a condition that the second power class is applied. On the other hand, switch SW222 is closed under the condition that the first power class and the third power class are applied and is open under the condition that the second power class is applied. Stated differently, under the condition that the first power class and the third power class are applied, at least one end of inductor L223 is not connected to a path between input terminal T241 and output terminal T242, and one of two ends of capacitor C223 is connected to the path between input terminal T241 and output terminal T242 and the remaining one of the two ends is connected to the ground. On the other hand, under the condition that the second power class is applied, two ends of inductor L223 are connected to the path between input terminal T241 and output terminal T242, and at least one end of capacitor C223 is not connected to the path between input terminal T241 and output terminal T242 or to the ground.

Accordingly, a load impedance viewed from node N1 is higher under the condition that the first power class and the third power class are applied and is lower under the condition that the second power class is applied. At this time, capacitor C221 and transformer 42 function as an impedance inverter. As a result, the load impedance viewed from power amplifiers 11 and 12 is adjusted to a lower first impedance (3 ohm, for example) under the condition that the first power class and the third power class are applied, and is adjusted to a higher second impedance (6 ohm, for example) under the condition that the second power class is applied.

### 2.3 Advantageous Effects and Others

As described above, radio frequency circuit 1A according to the present embodiment is radio frequency circuit 1A configured to support a first power class and a second power class whose maximum output power is lower than a maximum output power of the first power class, radio frequency circuit 1A including: power amplifier 11; and variable load matching circuit 23 or 24 connected to an output end of power amplifier 11. Under a condition that the first power class is applied, power supply voltage Vcc1 is supplied to power amplifier 11, and a load impedance viewed from power amplifier 11 is adjusted to a first impedance by variable load matching circuit 23 or 24. Under a condition that the second power class is applied, power supply voltage Vcc2 is supplied to power amplifier 11, and the load impedance viewed from power amplifier 11 is adjusted to a second impedance by variable load matching circuit 23 or 24. Power supply voltage Vcc1 is higher than power supply voltage Vcc2, and the first impedance is lower than the second impedance.

According to this, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1A according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and the load impedance viewed from power amplifier 11 may be adjusted to the first impedance by variable load matching circuit 23 or 24.

According to this, in the third power class between the first power class and the second power class, the same power supply voltage as in the second power class is supplied, and the load impedance is adjusted to the same load impedance as in the first power class. Thus, power efficiency can be improved by reducing an increase in power supply voltage in the third power class.

For example, in radio frequency circuit 1A according to the present embodiment, variable load matching circuit 23 may include: capacitor C213 and switch SW211 and/or switch SW212 connected in series between power amplifier 11 and antenna connection terminal 100; and capacitor C214 and switch SW213 and/or switch SW214 connected in parallel to capacitor C213 and switch SW211 and/or switch SW212, between power amplifier 11 and antenna connection terminal 100, capacitor C214 and switch SW213 and/or switch SW214 being connected in series, a capacitance of capacitor C213 may be greater than a capacitance of capacitor C214, under the condition that the first power class is applied, switch SW211 and/or switch SW212 may be closed, and switch SW213 and/or switch SW214 may be open, and under the condition that the second power class is applied, switch SW211 and/or switch SW212 may be open, and switch SW213 and/or switch SW214 may be closed.

According to this, the load impedance viewed from power amplifier 11 can be adjusted to the first impedance or the second impedance by switching between capacitors C213 and C214 on the signal path.

For example, in radio frequency circuit 1A according to the present embodiment, variable load matching circuit 24 may include: inductor L222 connected between power amplifier 11 and antenna connection terminal 100; inductor L223 and switch SW221 connected in parallel to inductor L222, between power amplifier 11 and antenna connection terminal 100, inductor L223 and switch SW221 being connected in series; capacitor C222 connected between ground and a path between power amplifier 11 and antenna connection terminal 100; and capacitor C223 and switch SW222 connected in parallel to capacitor C222, between the ground and the path between power amplifier 11 and antenna connection terminal 100, capacitor C223 and switch SW222 being connected in series, under the condition that the first power class is applied, switch SW221 may be open, and switch SW222 may be closed, and under the condition that the second power class is applied, switch SW221 may be closed, and switch SW222 may be open.

According to this, in the second power class, the load impedance viewed from power amplifier 11 can be adjusted to the second impedance by connecting inductor L222 on the signal path in parallel to inductor L223 and connecting capacitor C223 between the signal path and the ground. In particular, switch SW221 on the signal path is not closed in the first power class, and thus a signal loss due to switch SW221 can be reduced.

For example, radio frequency circuit 1A according to the present embodiment may further include: power amplifier 12; and transformer 42 that includes primary coil L421 and secondary coil L422, primary coil L421 including two ends one of which is connected to the output end of power amplifier 11 and a remaining one of which is connected to an output end of power amplifier 12, secondary coil L422 including an end connected to variable load matching circuit 23 or 24. Under the condition that the first power class is applied, power supply voltage Vcc1 may be supplied to power amplifier 11 and power amplifier 12, and a load impedance viewed from power amplifier 11 and power amplifier 12 may be adjusted to the first impedance by variable load matching circuit 23 or 24, and under the condition that the second power class is applied, power supply voltage Vcc2 may be supplied to power amplifier 11 and power amplifier 12, and the load impedance viewed from power amplifier 11 and power amplifier 12 may be adjusted to the second impedance by variable load matching circuit 23 or 24.

According to this, a radio frequency signal can be amplified by using two power amplifiers 11 and 12, and thus maximum output powers that power amplifiers 11 and 12 are to have in the first power class can be decreased.

### Embodiment 3

Next, Embodiment 3 is to be described. The present embodiment is different from Embodiments 1 and 2 above mainly in that a differential-amplifier type amplifier circuit is used as a power amplifier circuit and operation of one of the two power amplifiers is halted in the second power class. In the following, the present embodiment is to be described with reference to the drawings, focusing on different points from Embodiments 1 and 2 above.

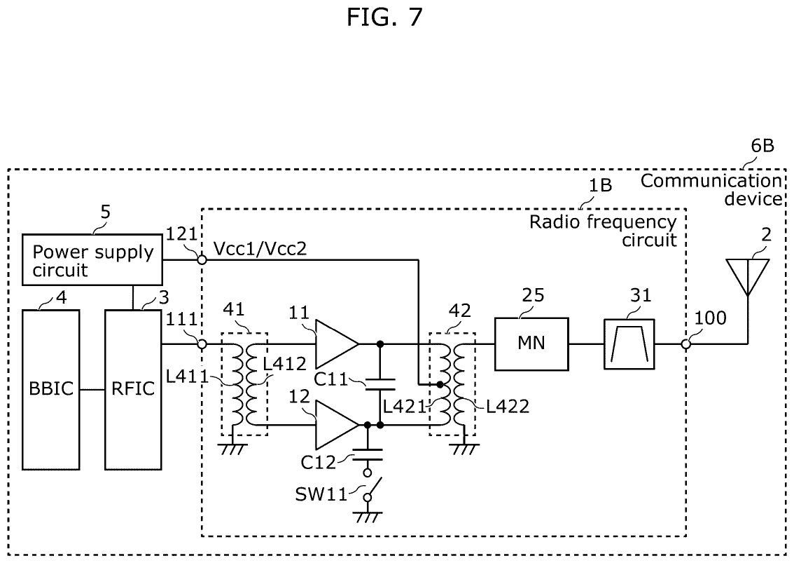

A circuit configuration of communication device 6B and radio frequency circuit 1B according to the present embodiment is to be described with reference to FIG. 7. FIG. 7 illustrates a circuit configuration of communication device 6B according to the present embodiment.

Note that FIG. 7 illustrates an exemplary circuit configuration, and communication device 6B and radio frequency circuit 1B may be implemented using any of various types of circuit implementations and circuit technologies. Thus, the description of communication device 6B and radio frequency circuit 1B provided below should not be interpreted in a limited manner.

Communication device 6B is the same as communication device 6, except that radio frequency circuit 1B is included instead of radio frequency circuit 1, and thus a description thereof is omitted.

### 3.1 Circuit Configuration of Radio Frequency Circuit 1B

Radio frequency circuit 1B according to the present embodiment is to be described with reference to FIG. 7. Radio frequency circuit 1B includes power amplifiers 11 and 12, variable load matching circuit 25, filter 31, transformers 41 and 42, capacitors C11 and C12, switch SW11, antenna connection terminal 100, input terminal 111, and power supply voltage terminal 121. Radio frequency circuit 1B corresponds to a circuit resulting from replacing variable load matching circuit 23 or 24 in radio frequency circuit 1A according to Embodiment 2 with variable load matching circuit 25 and adding capacitor C12 and switch SW11 to radio frequency circuit 1A.

Capacitor C12 and switch SW11 are an example of a third capacitor and an example of a third switch, respectively, and are connected in series between the ground and a path between power amplifier 12 and transformer 42. Here, switch SW11 is connected between capacitor C12 and the ground, but capacitor C12 may be connected between switch SW11 and the ground.

With such a circuit configuration, the operation of power amplifier 12 is halted under a condition that the second power class and the third power class are applied. Conversely, the operation of power amplifier 12 is not halted under a condition that the first power class is applied. For example, the operation of power amplifier 12 is halted by stopping supply of a bias and/or a power supply voltage to power amplifier 12 in the second power class and the third power class. At this time, a radio frequency signal amplified by power amplifier 11 is transferred to variable load matching circuit 25 via transformer 42, by closing switch SW11. Conversely, in the first power class, by supplying a bias and power supply voltage Vcc1 to power amplifier 12 and opening switch SW11, radio frequency signals are amplified by power amplifiers 11 and 12, the amplified radio frequency signals are combined by transformer 42, and the resultant signal is transferred to variable load matching circuit 25.

Variable load matching circuit 25 is a variable impedance matching circuit configured to adjust a load impedance viewed from power amplifiers 11 and 12, according to a power class.

### 3.2 Circuit Configuration of Variable Load Matching Circuit 25

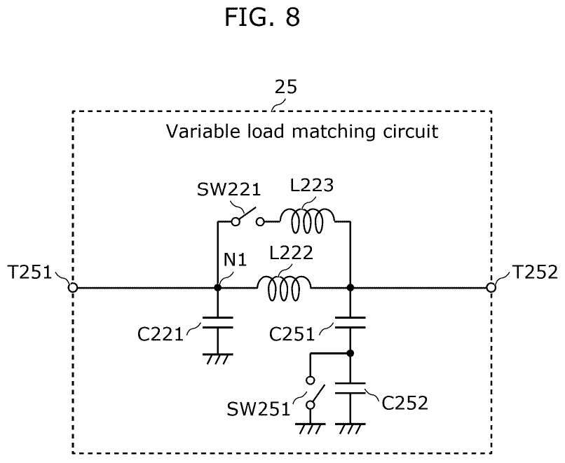

Here, a circuit configuration of variable load matching circuit 25 according to the present embodiment is to be described with reference to FIG. 8. FIG. 8 illustrates a circuit configuration of variable load matching circuit 25 according to the present embodiment.

Note that FIG. 8 illustrates an exemplary circuit configuration, and variable load matching circuit 25 may be implemented using any of various types of circuit implementations and circuit technologies. Thus, the description of variable load matching circuit 25 provided below should not be interpreted in a limited manner.

Variable load matching circuit 25 includes inductors L222 and L223, capacitors C221, C251, and C252, switches SW221 and SW251, input terminal T251, and output terminal T252. Variable load matching circuit 25 corresponds to a circuit resulting from replacing capacitors C222 and C223 and switch SW222 in variable load matching circuit 24 according to Embodiment 2 with capacitors C251 and C252 and switch SW251 and replacing input terminal T241 and output terminal T242 in variable load matching circuit 24 with input terminal T251 and output terminal T252.

Input terminal T251 is connected to secondary coil L422 of transformer 42 outside variable load matching circuit 25, and is connected to inductors L222 and L223 inside variable load matching circuit 25. Output terminal T252 is connected to antenna connection terminal 100 via filter 31 outside variable load matching circuit 25, and is connected to inductors L222 and L223 inside variable load matching circuit 25.

Inductor L222 is an example of a first inductor and is connected between input terminal T251 and output terminal T252.

Inductor L223 and switch SW221 are an example of a second inductor and an example of a first switch, respectively, are connected between input terminal T251 and output terminal T252 in parallel to inductor L222, and are connected in series.

Capacitors C251 and C252 are an example of a first capacitor and an example of a second capacitor, respectively, and are connected in series between the ground and a path between output terminal T252 and inductors L222 and L223.

Switch SW251 is an example of a second switch, and is connected between the ground and a path between capacitors C251 and C252.

With such a connection configuration, switch SW221 is open under a condition that the first power class and the third power class are applied and is closed under a condition that the second power class is applied. On the other hand, switch SW251 is closed under the condition that the first power class and the third power class are applied and is open under the condition that the second power class is applied. Stated differently, under the condition that the first power class and the third power class are applied, at least one end of inductor L223 is not connected to a path between input terminal T251 and output terminal T252, and one end of capacitor C251 is connected to the ground not via capacitor C252. On the other hand, under the condition that the second power class is applied, two ends of inductor L223 are connected to the path between input terminal T251 and output terminal T252, and one end of capacitor C251 is connected to the ground via capacitor C252.

Accordingly, a load impedance viewed from node N1 is higher under the condition that the first power class and the third power class are applied and is lower under the condition that the second power class is applied. At this time, capacitor C221 and transformer 42 function as an impedance inverter. As a result, the load impedance viewed from power amplifiers 11 and 12 is adjusted to a lower first impedance (3 ohm, for example) under the condition that the first power class and the third power class are applied, and the load impedance viewed from power amplifier 11 is adjusted to a higher second impedance (6 ohm, for example) under the condition that the second power class is applied.

### 3.3 Advantageous Effects and Others

As described above, radio frequency circuit 1B according to the present embodiment is radio frequency circuit 1B configured to support a first power class and a second power class whose maximum output power is lower than a maximum output power of the first power class, radio frequency circuit 1B including: power amplifier 11; and variable load matching circuit 25 connected to an output end of power amplifier 11. Under a condition that the first power class is applied, power supply voltage Vcc1 is supplied to power amplifier 11, and a load impedance viewed from power amplifier 11 is adjusted to a first impedance by variable load matching circuit 25. Under a condition that the second power class is applied, power supply voltage Vcc2 is supplied to power amplifier 11, and the load impedance viewed from power amplifier 11 is adjusted to a second impedance by variable load matching circuit 25. Power supply voltage Vcc1 is higher than power supply voltage Vcc2, and the first impedance is lower than the second impedance.

According to this, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1B according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and the load impedance viewed from power amplifier 11 may be adjusted to the first impedance by variable load matching circuit 25.

According to this, in the third power class between the first power class and the second power class, the same power supply voltage as that in the second power class is supplied, and the load impedance is adjusted to the same load impedance as in the first power class. Thus, power efficiency can be improved by reducing an increase in power supply voltage in the third power class.

For example, radio frequency circuit 1B according to the present embodiment may further include: power amplifier 12; and transformer 42 that includes primary coil L421 and secondary coil L422, primary coil L421 including two ends one of which is connected to the output end of power amplifier 11 and a remaining one of which is connected to an output end of power amplifier 12, secondary coil L422 including an end connected to variable load matching circuit 25. Under the condition that the first power class is applied, power supply voltage Vcc1 may be supplied to power amplifier 11 and power amplifier 12, and a load impedance viewed from power amplifier 11 and power amplifier 12 may be adjusted to the first impedance by variable load matching circuit 25, and under the condition that the second power class is applied, power supply voltage Vcc2 may be supplied to power amplifier 11, the load impedance viewed from power amplifier 11 may be adjusted to the second impedance by variable load matching circuit 25, and operation of power amplifier 12 may be halted.

According to this, radio frequency signals can be amplified by using two power amplifiers 11 and 12, and thus maximum output powers that power amplifiers 11 and 12 are to have in the first power class can be decreased. Furthermore, the operation of power amplifier 12 can be halted in the second power class with a lower maximum output power, and thus power efficiency in the second power class can be prevented from decreasing.

For example, in radio frequency circuit 1B according to the present embodiment, variable load matching circuit 25 may include: inductor L222 connected between secondary coil L422 and antenna connection terminal 100; inductor L223 and switch SW221 connected in parallel to inductor L222, between secondary coil L422 and antenna connection terminal 100, inductor L223 and switch SW221 being connected in series; capacitor C251 and capacitor C252 connected in series between ground and a path between power amplifier 11 and antenna connection terminal 100; and switch SW251 connected between the ground and a path between capacitor C251 and capacitor C252. Radio frequency circuit 1B may further include capacitor C12 and switch SW11 connected in series between the ground and a path between power amplifier 12 and primary coil L421. Under the condition that the first power class is applied, switch SW221 and switch SW11 may be open, and switch SW251 may be closed, and under the condition that the second power class is applied, switch SW221 and switch SW11 may be closed, and switch SW251 may be open.

According to this, radio frequency signals can be amplified by using two power amplifiers 11 and 12, and thus maximum output powers that power amplifiers 11 and 12 are to have in the first power class can be decreased. Furthermore, the operation of power amplifier 12 can be halted in the second power class with a lower maximum output power, and thus power efficiency in the second power class can be prevented from decreasing.

### Embodiment 4

Next, Embodiment 4 is to be described. The present embodiment is different from Embodiment 1 above mainly in that a Wilkinson amplifier circuit is used as a power amplifier circuit. In the following, the present embodiment is to be described with reference to the drawings, focusing on different points from Embodiment 1 above.

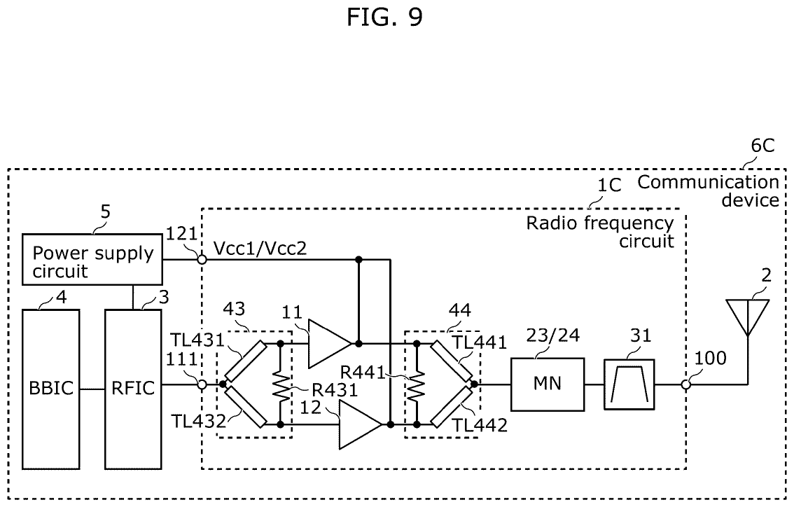

A circuit configuration of communication device 6C and radio frequency circuit 1C according to the present embodiment is to be described with reference to FIG. 9. FIG. 9 illustrates a circuit configuration of communication device 6C according to the present embodiment.

Note that FIG. 9 illustrates an exemplary circuit configuration, and communication device 6C and radio frequency circuit 1C may be implemented using any of various types of circuit implementations and circuit technologies. Thus, the description of communication device 6C and radio frequency circuit 1C provided below should not be interpreted in a limited manner.

Communication device 6C is the same as communication device 6, except that radio frequency circuit 1C is included instead of radio frequency circuit 1, and thus a description thereof is omitted.

### 4.1 Circuit Configuration of Radio Frequency Circuit 1C

Radio frequency circuit 1C according to the present embodiment is to be described with reference to FIG. 9. Radio frequency circuit 1C includes power amplifiers 11 and 12, variable load matching circuit 23 or 24, filter 31, Wilkinson divider 43, Wilkinson coupler 44, antenna connection terminal 100, input terminal 111, and power supply voltage terminal 121.

Power amplifier 11 is an example of a first power amplifier. The input end of power amplifier 11 is connected to Wilkinson divider 43. The output end of power amplifier 11 is connected to Wilkinson coupler 44. Power amplifier 11 can amplify one of in-phase signals output from Wilkinson divider 43.

Power amplifier 12 is an example of a second power amplifier. The input end of power amplifier 12 is connected to Wilkinson divider 43. The output end of power amplifier 12 is connected to Wilkinson coupler 44. Power amplifier 12 can amplify the other of the in-phase signals output from Wilkinson divider 43.

Power amplifiers 11 and 12 can support the first power class, the second power class, and the third power class. Under a condition that the first power class is applied, power supply voltage Vcc1 is supplied to power amplifiers 11 and 12, whereas in a state in which the second power class and the third power class are applied, power supply voltage Vcc2 is supplied to power amplifiers 11 and 12. Note that power amplifiers 11 and 12 may not be able to support the third power class.

Wilkinson divider 43 includes transfer lines TL431 and TL432 and resistor R431. Transfer line TL431 is connected between input terminal 111 and the input end of power amplifier 11. Transfer line TL432 is connected between input terminal 111 and the input end of power amplifier 12. Resistor R431 is connected between the input end of power amplifier 11 and the input end of power amplifier 12, in parallel to transfer lines TL431 and TL432.

With this connection configuration, Wilkinson divider 43 can divide a radio frequency signal supplied from RFIC 3 via input terminal 111 into two in-phase radio frequency signals. The divided two radio frequency signals (that is, in-phase signals) are supplied to power amplifiers 11 and 12.

Note that Wilkinson divider 43 may not be included in radio frequency circuit 1C. In this case, radio frequency circuit 1C may include two input terminals 111 for receiving in-phase signals from RFIC 3, for example.

Wilkinson coupler 44 includes transfer lines TL441 and TL442 and resistor R441. Transfer line TL441 is an example of a first transfer line, and is connected between the output end of power amplifier 11 and variable load matching circuit 23 or 24. Transfer line TL442 is an example of a second transfer line, and is connected between the output end of power amplifier 12 and variable load matching circuit 23 or 24. Resistor R441 is connected between the output end of power amplifier 11 and the output end of power amplifier 12, in parallel to transfer lines TL441 and TL442.

With this connection configuration, Wilkinson coupler 44 can combine in-phase signals amplified by power amplifiers 11 and 12 into one radio frequency signal. The combined radio frequency signal is transferred to antenna connection terminal 100 via variable load matching circuit 23 or 24 and filter 31.

Note that quarter-wavelength transfer lines may be used as transfer lines TL431, TL432, TL441, and TL442, but transfer lines TL431, TL432, TL441, and TL442 are not limited thereto. For example, LC circuits may be used as transfer lines TL431, TL432, TL441, and TL442.

### 4.2 Advantageous Effects and Others

As described above, radio frequency circuit 1C according to the present embodiment is radio frequency circuit 1C configured to support a first power class and a second power class whose maximum output power is lower than a maximum output power of the first power class, radio frequency circuit 1C including: power amplifier 11; and variable load matching circuit 23 or 24 connected to an output end of power amplifier 11. Under a condition that the first power class is applied, power supply voltage Vcc1 is supplied to power amplifier 11, and a load impedance viewed from power amplifier 11 is adjusted to a first impedance by variable load matching circuit 23 or 24. Under a condition that the second power class is applied, power supply voltage Vcc2 is supplied to power amplifier 11, and the load impedance viewed from power amplifier 11 is adjusted to a second impedance by variable load matching circuit 23 or 24. Power supply voltage Vcc1 is higher than power supply voltage Vcc2, and the first impedance is lower than the second impedance.

According to this, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1C according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and the load impedance viewed from power amplifier 11 may be adjusted to the first impedance by variable load matching circuit 23 or 24.

According to this, in the third power class between the first power class and the second power class, the same power supply voltage as in the second power class is supplied, and the load impedance is adjusted to the same load impedance as in the first power class. Thus, power efficiency can be improved by reducing an increase in power supply voltage in the third power class.

For example, in radio frequency circuit 1C according to the present embodiment, variable load matching circuit 23 may include: capacitor C213 and switch SW211 and/or switch SW212 connected in series between power amplifier 11 and antenna connection terminal 100; and capacitor C214 and switch SW213 and/or switch SW214 connected in parallel to capacitor C213 and switch SW211 and/or switch SW212, between power amplifier 11 and antenna connection terminal 100, capacitor C214 and switch SW213 and/or switch SW214 being connected in series, a capacitance of capacitor C213 may be greater than a capacitance of capacitor C214, under the condition that the first power class is applied, switch SW211 and/or switch SW212 may be closed, and switch SW213 and/or switch SW214 may be open, and under the condition that the second power class is applied, switch SW211 and/or switch SW212 may be open, and switch SW213 and/or switch SW214 may be closed.

According to this, the load impedance viewed from power amplifier 11 can be adjusted to the first impedance or the second impedance by switching between capacitors C213 and C214 on the signal path.

For example, in radio frequency circuit 1C according to the present embodiment, variable load matching circuit 24 may include: inductor L222 connected between power amplifier 11 and antenna connection terminal 100; inductor L223 and switch SW221 connected in parallel to inductor L222, between power amplifier 11 and antenna connection terminal 100, inductor L223 and switch SW221 being connected in series; capacitor C222 connected between ground and a path between power amplifier 11 and the antenna connection terminal; and capacitor C223 and switch SW222 connected in parallel to capacitor C222, between the ground and the path between power amplifier 11 and antenna connection terminal 100, capacitor C223 and switch SW222 being connected in series, under the condition that the first power class is applied, switch SW221 may be open, and switch SW222 may be closed, and under the condition that the second power class is applied, switch SW221 may be closed, and switch SW222 may be open.

According to this, in the second power class, the load impedance viewed from power amplifier 11 can be adjusted to the second impedance by connecting inductor L222 on the signal path in parallel to inductor L223 and connecting capacitor C223 between the signal path and the ground. In particular, switch SW221 on the signal path is not closed in the first power class, and thus a signal loss due to switch SW221 can be reduced.

For example, radio frequency circuit 1C according to the present embodiment may further include: power amplifier 12; transfer line TL441 connected between the output end of power amplifier 11 and variable load matching circuit 23 or 24; transfer line TL442 connected between an output end of power amplifier 12 and variable load matching circuit 23 or 24; and resistor R441 connected in parallel to transfer line TL441 and transfer line TL442, between the output end of power amplifier 11 and the output end of power amplifier 12. Under the condition that the first power class is applied, power supply voltage Vcc1 may be supplied to power amplifier 11 and power amplifier 12, and a load impedance viewed from power amplifier 11 and power amplifier 12 may be adjusted to the first impedance by variable load matching circuit 23 or 24, and under the condition that the second power class is applied, power supply voltage Vcc2 may be supplied to power amplifier 11 and power amplifier 12, and the load impedance viewed from power amplifier 11 and power amplifier 12 may be adjusted to the second impedance by variable load matching circuit 23 or 24.

According to this, radio frequency signals can be amplified by using two power amplifiers 11 and 12, and thus maximum output powers that power amplifiers 11 and 12 are to have in the first power class can be decreased.

### Embodiment 5

Next, Embodiment 5 is to be described. The present embodiment is different from Embodiments 1 and 4 above mainly in that a Wilkinson amplifier circuit is used as a power amplifier circuit and operation of one of the two power amplifiers is halted in the second power class. In the following, the present embodiment is to be described with reference to the drawings, focusing on different points from Embodiments 1 and 4 above.

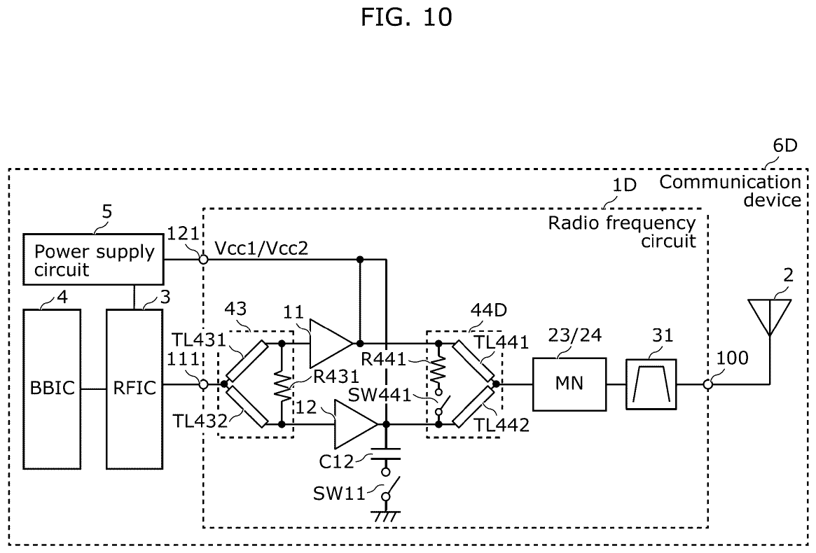

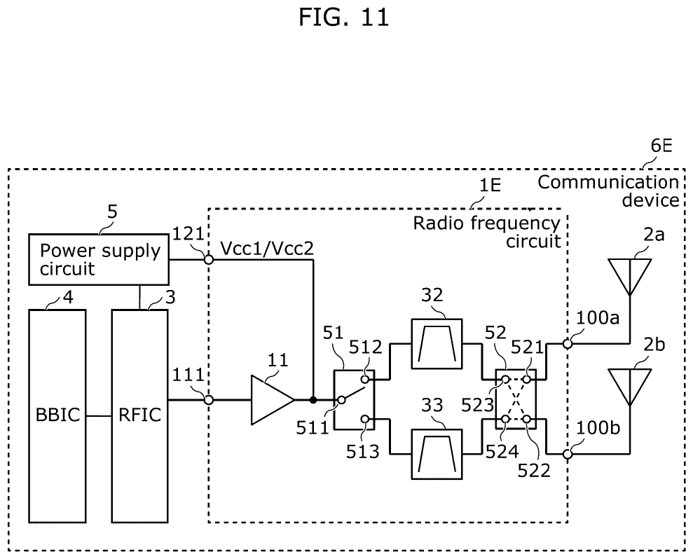

A circuit configuration of communication device 6D and radio frequency circuit 1D according to the present embodiment is to be described with reference to FIG. 10. FIG. 10 illustrates a circuit configuration of communication device 6D according to the present embodiment.

Note that FIG. 10 illustrates an exemplary circuit configuration, and communication device 6D and radio frequency circuit 1D may be implemented using any of various types of circuit implementations and circuit technologies. Thus, the description of communication device 6D and radio frequency circuit 1D provided below should not be interpreted in a limited manner.

Communication device 6D is the same as communication device 6, except that radio frequency circuit 1D is included instead of radio frequency circuit 1, and thus a description thereof is omitted.

### 5.1 Circuit Configuration of Radio Frequency Circuit 1D

Radio frequency circuit 1D according to the present embodiment is to be described with reference to FIG. 10. Radio frequency circuit 1D includes power amplifiers 11 and 12, variable load matching circuit 23 or 24, filter 31, Wilkinson divider 43, Wilkinson coupler 44D, capacitor C12, switch SW11, antenna connection terminal 100, input terminal 111, and power supply voltage terminal 121. Radio frequency circuit 1D corresponds to a circuit resulting from replacing Wilkinson coupler 44 in radio frequency circuit 1C according to Embodiment 4 with Wilkinson coupler 44D and adding capacitor C12 and switch SW11 to radio frequency circuit 1C.

Wilkinson coupler 44D includes switch SW441 (an example of a fourth switch) in addition to transfer lines TL441 and TL442 and resistor R441. Switch SW441 and resistor R441 are connected between the output end of power amplifier 11 and the output end of power amplifier 12, in parallel to transfer lines TL441 and TL442, and are connected in series to each other.

Capacitor C12 and switch SW11 are an example of a third capacitor and an example of a third switch, respectively, and are connected in series between the ground and a path between power amplifier 12 and Wilkinson coupler 44D. Here, switch SW11 is connected between capacitor C12 and the ground, but capacitor C12 may be connected between switch SW11 and the ground.

With such a circuit configuration, the operation of power amplifier 12 is halted under a condition that the second power class and the third power class are applied. Conversely, the operation of power amplifier 12 is not halted under a condition that the first power class is applied. For example, in the second power class and the third power class, by stopping supply of a bias to power amplifier 12, closing switch SW11, and opening switch SW441, the operation of power amplifier 12 is halted, and a radio frequency signal amplified by power amplifier 11 is transferred to variable load matching circuit 23 or 24. In the first power class, by supplying a bias to power amplifier 12 and opening switch SW11, the operation of power amplifier 12 is started/continued, radio frequency signals amplified by power amplifiers 11 and 12 are combined, and the resultant signal is transferred to variable load matching circuit 23 or 24.

### 5.2 Advantageous Effects and Others

As described above, radio frequency circuit 1D according to the present embodiment is radio frequency circuit 1D configured to support a first power class and a second power class whose maximum output power is lower than a maximum output power of the first power class, radio frequency circuit 1D including: power amplifier 11; and variable load matching circuit 23 or 24 connected to an output end of power amplifier 11. Under a condition that the first power class is applied, power supply voltage Vcc1 is supplied to power amplifier 11, and a load impedance viewed from power amplifier 11 is adjusted to a first impedance by variable load matching circuit 23 or 24. Under a condition that the second power class is applied, power supply voltage Vcc2 is supplied to power amplifier 11, and the load impedance viewed from power amplifier 11 is adjusted to a second impedance by variable load matching circuit 23 or 24. Power supply voltage Vcc1 is higher than power supply voltage Vcc2, and the first impedance is lower than the second impedance.

According to this, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1D according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and the load impedance viewed from power amplifier 11 may be adjusted to the first impedance by variable load matching circuit 23 or 24.

According to this, in the third power class between the first power class and the second power class, the same power supply voltage as in the second power class is supplied, and the load impedance is adjusted to the same load impedance as in the first power class. Thus, power efficiency can be improved by reducing an increase in power supply voltage in the third power class.

For example, in radio frequency circuit 1D according to the present embodiment, variable load matching circuit 23 may include: capacitor C213 and switch SW211 and/or switch SW212 connected in series between power amplifier 11 and antenna connection terminal 100; and capacitor C214 and switch SW213 and/or switch SW214 connected in parallel to capacitor C213 and switch SW211 and/or switch SW212, between power amplifier 11 and antenna connection terminal 100, capacitor C214 and switch SW213 and/or switch SW214 being connected in series, a capacitance of capacitor C213 may be greater than a capacitance of capacitor C214, under the condition that the first power class is applied, switch SW211 and/or switch SW212 may be closed, and switch SW213 and/or switch SW214 may be open, and under the condition that the second power class is applied, switch SW211 and/or switch SW212 may be open, and switch SW213 and/or switch SW214 may be closed.

According to this, the load impedance viewed from power amplifier 11 can be adjusted to the first impedance or the second impedance by switching between capacitors C213 and C214 on the signal path.

For example, in radio frequency circuit 1D according to the present embodiment, variable load matching circuit 24 may include: inductor L222 connected between power amplifier 11 and antenna connection terminal 100; inductor L223 and switch SW221 connected in parallel to inductor L222, between power amplifier 11 and antenna connection terminal 100, inductor L223 and switch SW221 being connected in series; capacitor C222 connected between ground and a path between power amplifier 11 and antenna connection terminal 100; and capacitor C223 and switch SW222 connected in parallel to capacitor C222, between the ground and the path between power amplifier 11 and antenna connection terminal 100, capacitor C223 and switch SW222 being connected in series, under the condition that the first power class is applied, switch SW221 may be open, and switch SW222 may be closed, and under the condition that the second power class is applied, switch SW221 may be closed, and switch SW222 may be open.

According to this, in the second power class, the load impedance viewed from power amplifier 11 can be adjusted to the second impedance by connecting inductor L222 on the signal path in parallel to inductor L223 and connecting capacitor C223 between the signal path and the ground. In particular, switch SW221 on the signal path is not closed in the first power class, and thus a signal loss due to switch SW221 can be reduced.

For example, radio frequency circuit 1D according to the present embodiment may further include: power amplifier 12; transfer line TL441 connected between the output end of power amplifier 11 and variable load matching circuit 23 or 24; transfer line TL442 connected between an output end of power amplifier 12 and variable load matching circuit 23 or 24; and resistor R441 connected in parallel to transfer line TL441 and transfer line TL442, between the output end of power amplifier 11 and the output end of power amplifier 12. Under the condition that the first power class is applied, power supply voltage Vcc1 may be supplied to power amplifier 11 and power amplifier 12, and a load impedance viewed from power amplifier 11 and power amplifier 12 may be adjusted to the first impedance by variable load matching circuit 23 or 24, and under the condition that the second power class is applied, power supply voltage Vcc2 may be supplied to power amplifier 11, the load impedance viewed from power amplifier 11 may be adjusted to the second impedance by variable load matching circuit 23 or 24, and operation of power amplifier 12 may be halted.

According to this, radio frequency signals can be amplified by using two power amplifiers 11 and 12, and thus maximum output powers that power amplifiers 11 and 12 are to have in the first power class can be decreased. Furthermore, the operation of power amplifier 12 can be halted in the second power class with a lower maximum output power, and thus power efficiency in the second power class can be prevented from decreasing.

For example, radio frequency circuit 1D according to the present embodiment may further include: capacitor C12 and switch SW11 connected in series between ground and a path between power amplifier 12 and transfer line TL442; and switch SW441 connected in series to resistor R441, between the output end of power amplifier 11 and the output end of power amplifier 12. Under the condition that the first power class is applied, switch SW11 may be open, and switch SW441 may be closed, and under the condition that the second power class is applied, switch SW11 may be closed, and switch SW441 may be open.

According to this, radio frequency signals can be amplified by using two power amplifiers 11 and 12, and thus maximum output powers that power amplifiers 11 and 12 are to have in the first power class can be decreased. Furthermore, the operation of power amplifier 12 can be halted in the second power class with a lower maximum output power, and thus power efficiency in the second power class can be prevented from decreasing.

Table 1 shows specific examples of combinations of passbands or supported bands of filter 31 and power classes, which can be used in Embodiments 1 to 5 above.

TABLE 1

| | Passband or | | | |
|---|---|---|---|---|
| | supported band | First power class | Second power class | Third power class |
| #1 | 5150-7125 MHz | PC1/PC1.5/PC2 | PC5@5150-7125 MHz | PC3@6425-7125 MHz |
| | | @6425-7125 MHz | | |
| #2 | 5925-7125 MHz | PC1/PC1.5/PC2 | PC5@5925-7125 MHz | PC3@6425-7125 MHz |
| | | @6425-7125 MHz | | |
| #3 | 6425-7125 MHz | PC1/PC1.5/PC2 | PC5@6425-7125 MHz | PC3@6425-7125 MHz |
| | | @6425-7125 MHz | | |
| #4 | n104 and n46/ | PC1/PC1.5/PC2 | PC5@n46/n96/n102 | PC3@n104 |
| | n96/n102 | @n104 | | |

### Embodiment 6

Next, Embodiment 6 is to be described. The present embodiment is different from Embodiment 1 above mainly in that a load impedance viewed from a power amplifier is adjusted by using two filters having different input impedances instead of the variable load matching circuit. In the following, the present embodiment is to be described with reference to the drawings, focusing on different points from Embodiment 1 above.

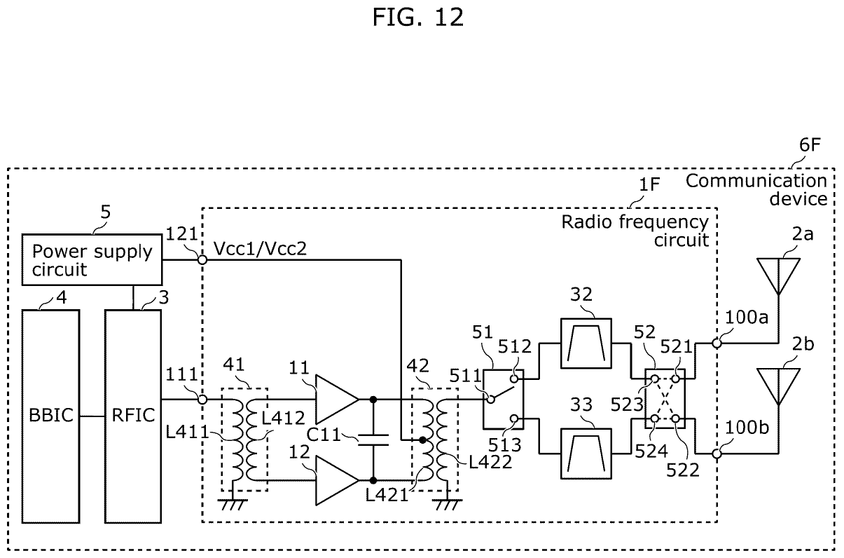

A circuit configuration of communication device 6E and radio frequency circuit 1E according to the present embodiment is to be described with reference to FIG. 11. FIG. 11 illustrates a circuit configuration of communication device 6E according to the present embodiment.

Note that FIG. 11 illustrates an exemplary circuit configuration, and communication device 6E and radio frequency circuit 1E may be implemented using any of various types of circuit implementations and circuit technologies. Thus, the description of communication device 6E and radio frequency circuit 1E provided below should not be interpreted in a limited manner.

### 6.1 Circuit Configuration of Communication Device 6E

First, communication device 6E according to the present embodiment is to be described with reference to FIG. 11. Communication device 6E includes radio frequency circuit 1E, antennas 2a and 2b, radio frequency integrated circuit (RFIC) 3, baseband integrated circuit (BBIC) 4, and power supply circuit 5.

Radio frequency circuit 1E transfers radio frequency signals between antennas 2a and 2b and RFIC 3. A circuit configuration of radio frequency circuit 1E is to be described later.

Antennas 2a and 2b are connected to antenna connection terminals 100a and 100b of radio frequency circuit 1E, respectively. Antennas 2a and 2b receive radio frequency signals from radio frequency circuit 1E and outputs the radio frequency signals to the outside of communication device 6E. Antennas 2a and 2b may receive radio frequency signals from the outside of communication device 6E and output the radio frequency signals to radio frequency circuit 1E. Note that at least one of antenna 2a or 2b may not be included in communication device 6E. Communication device 6E may further include one or more antennas in addition to antennas 2a and 2b.

### 6.2 Circuit Configuration of Radio Frequency Circuit 1E

Next, radio frequency circuit 1E according to the present embodiment is to be described with reference to FIG. 11. Radio frequency circuit 1E includes power amplifier 11, filters 32 and 33, switch circuits 51 and 52, antenna connection terminals 100a and 100b, input terminal 111, and power supply voltage terminal 121.

Antenna connection terminals 100a and 100b are external connection terminals of radio frequency circuit 1E, and are for supplying transmission signals to the outside of radio frequency circuit 1E. Antenna connection terminals 100a and 100b are connected to antennas 2a and 2b, respectively, outside radio frequency circuit 1E, and are connected to filters 32 and 33 via switch circuit 52 inside radio frequency circuit 1E. Note that one of antenna connection terminal 100a or 100b may not be included in radio frequency circuit 1E.

Power amplifier 11 is an example of a first power amplifier. The input end of power amplifier 11 is connected to input terminal 111. The output end of power amplifier 11 is selectively connected to filters 32 and 33 via switch circuit 51. Furthermore, power amplifier 11 is connected to power supply voltage terminal 121.

Similarly to Embodiment 1, power amplifier 11 can amplify radio frequency signals supplied from RFIC 3 via input end 111, by using power supply voltages Vcc1 and Vcc2 supplied from power supply circuit 5 via power supply voltage terminal 121. Power amplifier 11 can support a first power class, a second power class, and a third power class. Under a condition that the first power class is applied, power supply voltage Vcc1 is supplied to power amplifier 11, whereas under a condition that the second power class and the third power class are applied, power supply voltage Vcc2 is supplied to power amplifier 11. Note that power amplifier 11 may not be able to support the third power class.

Filter 32 is an example of a first filter, and is connected between power amplifier 11 and antenna connection terminals 100a and 100b. Specifically, one end of filter 32 is connected to power amplifier 11 via switch circuit 51, and another end of filter 32 is connected to antenna connection terminal 100a or 100b via switch circuit 52. Filter 32 supports a predetermined band and is a band pass filter having a passband that includes the predetermined band. Filter 32 has power durability for the first power class. A SAW filter, a BAW filter, an LC resonator filter, a dielectric resonator filter, or a combination of any of these may be used as filter 32, and furthermore, filter 32 is not limited to these.

Filter 33 is an example of a second filter, and is connected between power amplifier 11 and antenna connection terminals 100a and 100b. Specifically, one end of filter 33 is connected to power amplifier 11 via switch circuit 51, and another end of filter 33 is connected to antenna connection terminal 100a or 100b via switch circuit 52. Filter 33 is a band pass filter having a passband that includes a predetermined band, and has power durability for the second power class. A SAW filter, a BAW filter, an LC resonator filter, a dielectric resonator filter, or a combination of any of these may be used as filter 33, and furthermore, filter 33 is not limited to these.

Filters 32 and 33 have different input impedances. Specifically, the input impedance of filter 32 is lower than the input impedance of filter 33. Accordingly, a load impedance viewed from power amplifier 11 is adjusted to a lower first impedance under a condition that filter 32 is connected to power amplifier 11, whereas the load impedance viewed from power amplifier 11 is adjusted to a higher second impedance under a condition that power amplifier 11 is connected to filter 33.

Note that the input impedances of filters 32 and 33 can be identified by measuring an impedance at a center frequency of a predetermined band by using a network analyzer.

Switch circuit 51 is connected between power amplifier 11 and filters 32 and 33. Specifically, switch circuit 51 includes terminals 511 to 513. Terminal 511 is an example of a first terminal, and is connected to the output end of power amplifier 11. Terminal 512 is an example of a second terminal, and is connected to filter 32. Terminal 513 is an example of a third terminal, and is connected to filter 33.

With this connection configuration, switch circuit 51 can connect terminal 511 exclusively to terminal 512 or 513, based on a control signal from RFIC 3, for example. Thus, switch circuit 51 can selectively connect power amplifier 11 to filter 32 or 33. More specifically, switch circuit 51 can connect power amplifier 11 to filter 32 under a condition that the first power class and the third power class are applied, and can connect power amplifier 11 to filter 33 under a condition that the second power class is applied. Switch circuit 51 is a single-pole double-throw (SPDT) switch circuit, for example.

Switch circuit 52 is connected between filters 32 and 33 and antenna connection terminals 100a and 100b. Specifically, switch circuit 52 includes terminals 521 to 524. Terminal 521 is connected to antenna connection terminal 100a. Terminal 522 is connected to antenna connection terminal 100b. Terminal 523 is connected to filter 32. Terminal 524 is connected to filter 33.

With this connection configuration, switch circuit 52 can connect terminal 521 exclusively to terminal 523 or 524 and can connect terminal 522 exclusively to terminal 523 or 524, based on a control signal from RFIC 3, for example. Switch circuit 52 is a double-pole double-throw (DPDT) switch circuit, for example.

Note that switch circuit 52 may not be included in radio frequency circuit 1E. In this case, filters 32 and 33 may be fixedly connected to antenna connection terminals 100a and 100b, respectively.

### 6.3 Advantageous Effects and Others

As described above, radio frequency circuit 1E according to the present embodiment is radio frequency circuit 1E configured to support a first power class and a second power class whose maximum output power is lower than a maximum output power of the first power class, radio frequency circuit 1E including: power amplifier 11; filter 32; filter 33; and switch circuit 51 that includes terminal 511 connected to an output end of power amplifier 11, terminal 512 connected to filter 32, and terminal 513 connected to filter 33. Under a condition that the first power class is applied, power supply voltage Vcc1 is supplied to power amplifier 11, and filter 32 is connected to power amplifier 11 by switch circuit 51. Under a condition that the second power class is applied, power supply voltage Vcc2 is supplied to power amplifier 11, and filter 33 is connected to power amplifier 11 by switch circuit 51. Power supply voltage Vcc1 is higher than power supply voltage Vcc2, and an input impedance of filter 32 is lower than an input impedance of filter 33.

According to this, connection of power amplifier 12 can be switched between filters 32 and 33 having different input impedances according to which of the first power class or the second power class is applied, and thus the load impedance viewed from power amplifier 11 can be changed. Thus, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1E according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and filter 32 may be connected to power amplifier 11 by switch circuit 51.

According to this, in the third power class between the first power class and the second power class, the same power supply voltage as in the second power class is supplied, and filter 32 the same as in the first power class can be connected to power amplifier 11. Thus, power efficiency can be improved by reducing an increase in power supply voltage in the third power class.

### Embodiment 7

Next, Embodiment 7 is to be described. The present embodiment is different from Embodiment 6 above mainly in that a differential-amplifier type amplifier circuit is used as a power amplifier circuit. In the following, the present embodiment is to be described with reference to the drawings, focusing on different points from Embodiment 6 above.

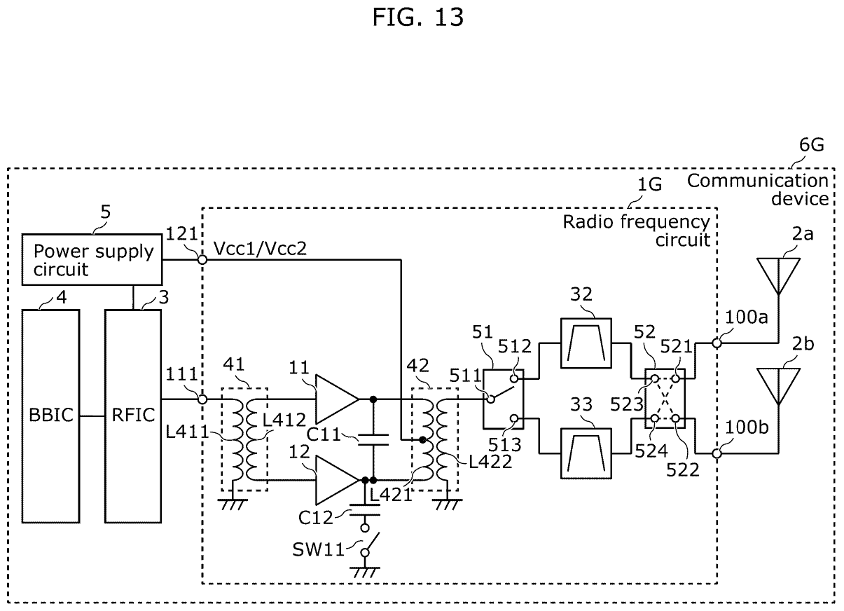

A circuit configuration of communication device 6F and radio frequency circuit 1F according to the present embodiment is to be described with reference to FIG. 12. FIG. 12 illustrates a circuit configuration of communication device 6F according to the present embodiment.

Note that FIG. 12 illustrates an exemplary circuit configuration, and communication device 6F and radio frequency circuit 1F may be implemented using any of various types of circuit implementations and circuit technologies. Thus, the description of communication device 6F and radio frequency circuit 1F provided below should not be interpreted in a limited manner.

Communication device 6F is the same as communication device 6E, except that radio frequency circuit 1F is included instead of radio frequency circuit 1E, and thus a description thereof is omitted.

Radio frequency circuit 1F includes power amplifiers 11 and 12, filters 32 and 33, transformers 41 and 42, switch circuits 51 and 52, capacitor C11, antenna connection terminals 100a and 100b, input terminal 111, and power supply voltage terminal 121. Note that radio frequency circuit 1F corresponds to a combination of the radio frequency circuits in Embodiments 2 and 6 above, and thus a detailed description thereof is omitted.

As described above, radio frequency circuit 1F according to the present embodiment is radio frequency circuit 1F configured to support a first power class and a second power class whose maximum output power is lower than a maximum output power of the first power class, radio frequency circuit 1F including: power amplifier 11; filter 32; filter 33; and switch circuit 51 that includes terminal 511 connected to an output end of power amplifier 11, terminal 512 connected to filter 32, and terminal 513 connected to filter 33. Under a condition that the first power class is applied, power supply voltage Vcc1 is supplied to power amplifier 11, and filter 32 is connected to power amplifier 11 by switch circuit 51. Under a condition that the second power class is applied, power supply voltage Vcc2 is supplied to power amplifier 11, and filter 33 is connected to power amplifier 11 by switch circuit 51. Power supply voltage Vcc1 is higher than power supply voltage Vcc2, and an input impedance of filter 32 is lower than an input impedance of filter 33.

According to this, connection of power amplifier 12 can be switched between filters 32 and 33 having different input impedances according to which of the first power class or the second power class is applied, and thus the load impedance viewed from power amplifier 11 can be changed. Thus, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1F according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and filter 32 may be connected to power amplifier 11 by switch circuit 51.

According to this, in the third power class between the first power class and the second power class, the same power supply voltage as in the second power class is supplied, and filter 32 the same as in the first power class can be connected to power amplifier 11. Thus, power efficiency can be improved by reducing an increase in power supply voltage in the third power class.

For example, radio frequency circuit 1F according to the present embodiment may further include: power amplifier 12; and transformer 42 that includes primary coil L421 and secondary coil L422, primary coil L421 including two ends one of which is connected to the output end of power amplifier 11 and a remaining one of which is connected to an output end of power amplifier 12, secondary coil L422 including an end connected to terminal 511 of switch circuit 51. Under the condition that the first power class is applied, power supply voltage Vcc1 may be supplied to power amplifier 11 and power amplifier 12, and filter 32 may be connected to transformer 42 by switch circuit 51, and under the condition that the second power class is applied, power supply voltage Vcc2 may be supplied to power amplifier 11 and power amplifier 12, and filter 33 may be connected to transformer 42 by switch circuit 51.

According to this, radio frequency signals can be amplified by using two power amplifiers 11 and 12, and thus maximum output powers that power amplifiers 11 and 12 are to have in the first power class can be decreased.

### Embodiment 8

Next, Embodiment 8 is to be described. The present embodiment is different from Embodiments 6 and 7 above mainly in that a differential-amplifier type amplifier circuit is used as a power amplifier circuit and operation of one of the two power amplifiers is halted in the second power class. In the following, the present embodiment is to be described with reference to the drawings, focusing on different points from Embodiments 6 and 7 above.

A circuit configuration of communication device 6G and radio frequency circuit 1G according to the present embodiment is to be described with reference to FIG. 13. FIG. 13 illustrates a circuit configuration of communication device 6G according to the present embodiment.

Note that FIG. 13 illustrates an exemplary circuit configuration, and communication device 6G and radio frequency circuit 1G may be implemented using any of various types of circuit implementations and circuit technologies. Thus, the description of communication device 6G and radio frequency circuit 1G provided below should not be interpreted in a limited manner.

Communication device 6G is the same as communication device 6E, except that radio frequency circuit 1G is included instead of radio frequency circuit 1E, and thus a description thereof is omitted.

Radio frequency circuit 1G includes power amplifiers 11 and 12, filters 32 and 33, transformers 41 and 42, switch circuits 51 and 52, capacitors C11 and C12, switch SW11, antenna connection terminals 100a and 100b, input terminal 111, and power supply voltage terminal 121. Note that radio frequency circuit 1G corresponds to a combination of the radio frequency circuits according to Embodiments 3 and 6 above, and thus a detailed description thereof is omitted.

As described above, radio frequency circuit 1G according to the present embodiment is radio frequency circuit 1G configured to support a first power class and a second power class whose maximum output power is lower than a maximum output power of the first power class, radio frequency circuit 1G including: power amplifier 11; filter 32; filter 33; and switch circuit 51 that includes terminal 511 connected to an output end of power amplifier 11, terminal 512 connected to filter 32, and terminal 513 connected to filter 33. Under a condition that the first power class is applied, power supply voltage Vcc1 is supplied to power amplifier 11, and filter 32 is connected to power amplifier 11 by switch circuit 51. Under a condition that the second power class is applied, power supply voltage Vcc2 is supplied to power amplifier 11, and filter 33 is connected to power amplifier 11 by switch circuit 51. Power supply voltage Vcc1 is higher than power supply voltage Vcc2, and an input impedance of filter 32 is lower than an input impedance of filter 33.

According to this, connection of power amplifier 12 can be switched between filters 32 and 33 having different input impedances according to which of the first power class or the second power class is applied, and thus the load impedance viewed from power amplifier 11 can be changed. Thus, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1G according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and filter 32 may be connected to power amplifier 11 by switch circuit 51.

According to this, in the third power class between the first power class and the second power class, the same power supply voltage as in the second power class is supplied, and filter 32 the same as in the first power class can be connected to power amplifier 11. Thus, power efficiency can be improved by reducing an increase in power supply voltage in the third power class.

For example, radio frequency circuit 1G according to the present embodiment may further include: power amplifier 12; and transformer 42 that includes primary coil L421 and secondary coil L422, primary coil L421 including two ends one of which is connected to the output end of power amplifier 11 and a remaining one of which is connected to an output end of power amplifier 12, secondary coil L422 including an end connected to terminal 511 of switch circuit 51. Under the condition that the first power class is applied, power supply voltage Vcc1 may be supplied to power amplifier 11 and power amplifier 12, and filter 32 may be connected to transformer 42 by switch circuit 51, and under the condition that the second power class is applied, power supply voltage Vcc2 may be supplied to power amplifier 11, filter 33 may be connected to transformer 42 by switch circuit 51, and operation of power amplifier 12 may be halted.

According to this, radio frequency signals can be amplified by using two power amplifiers 11 and 12, and thus maximum output powers that power amplifiers 11 and 12 are to have in the first power class can be decreased. Furthermore, the operation of power amplifier 12 can be halted in the second power class with a lower maximum output power, and thus power efficiency in the second power class can be prevented from decreasing.

### Embodiment 9

Next, Embodiment 9 is to be described. The present embodiment is different from Embodiment 6 above mainly in that a Wilkinson amplifier circuit is used as a power amplifier circuit. In the following, the present embodiment is to be described with reference to the drawings, focusing on different points from Embodiment 6 above.

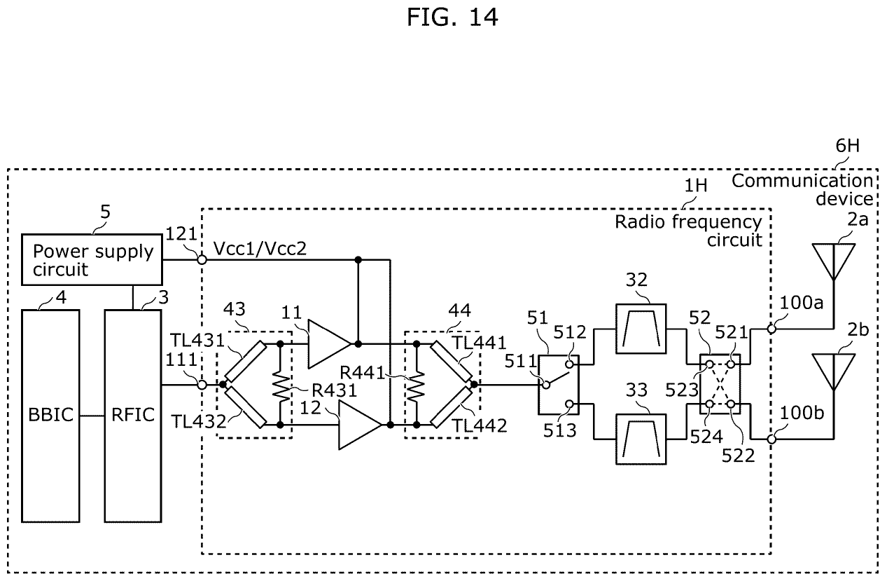

A circuit configuration of communication device 6H and radio frequency circuit 1H according to the present embodiment is to be described with reference to FIG. 14. FIG. 14 illustrates a circuit configuration of communication device 6H according to the present embodiment.

Note that FIG. 14 illustrates an exemplary circuit configuration, and communication device 6H and radio frequency circuit 1H may be implemented using any of various types of circuit implementations and circuit technologies. Thus, the description of communication device 6H and radio frequency circuit 1H provided below should not be interpreted in a limited manner.

Communication device 6H is the same as communication device 6E, except that radio frequency circuit 1H is included instead of radio frequency circuit 1E, and thus a description thereof is omitted.

Radio frequency circuit 1H includes power amplifiers 11 and 12, filters 32 and 33, Wilkinson divider 43, Wilkinson coupler 44, switch circuits 51 and 52, antenna connection terminals 100a and 100b, input terminal 111, and power supply voltage terminal 121. Note that radio frequency circuit 1H corresponds to a combination of the radio frequency circuits according to Embodiments 4 and 6 above, and thus a detailed description thereof is omitted.

As described above, radio frequency circuit 1H according to the present embodiment is radio frequency circuit 1H configured to support a first power class and a second power class whose maximum output power is lower than a maximum output power of the first power class, radio frequency circuit 1H including: power amplifier 11; filter 32; filter 33; and switch circuit 51 that includes terminal 511 connected to an output end of power amplifier 11, terminal 512 connected to filter 32, and terminal 513 connected to filter 33. Under a condition that the first power class is applied, power supply voltage Vcc1 is supplied to power amplifier 11, and filter 32 is connected to power amplifier 11 by switch circuit 51. Under a condition that the second power class is applied, power supply voltage Vcc2 is supplied to power amplifier 11, and filter 33 is connected to power amplifier 11 by switch circuit 51. Power supply voltage Vcc1 is higher than power supply voltage Vcc2, and an input impedance of filter 32 is lower than an input impedance of filter 33.

According to this, connection of power amplifier 12 can be switched between filters 32 and 33 having different input impedances according to which of the first power class or the second power class is applied, and thus the load impedance viewed from power amplifier 11 can be changed. Thus, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1H according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and filter 32 may be connected to power amplifier 11 by switch circuit 51.

According to this, in the third power class between the first power class and the second power class, the same power supply voltage as in the second power class is supplied, and filter 32 the same as in the first power class can be connected to power amplifier 11. Thus, power efficiency can be improved by reducing an increase in power supply voltage in the third power class.

For example, radio frequency circuit 1H according to the present embodiment may further include: power amplifier 12; transfer line TL441 connected between the output end of power amplifier 11 and terminal 511 of switch circuit 51; transfer line TL442 connected between an output end of power amplifier 12 and terminal 511 of switch circuit 51; and resistor R441 connected in parallel to transfer line TL441 and transfer line TL442, between the output end of power amplifier 11 and the output end of power amplifier 12. Under the condition that the first power class is applied, power supply voltage Vcc1 may be supplied to power amplifier 11 and power amplifier 12, and filter 32 may be connected to power amplifier 11 and power amplifier 12 by switch circuit 51, and under the condition that the second power class is applied, power supply voltage Vcc2 may be supplied to power amplifier 11 and power amplifier 12, and filter 33 may be connected to power amplifier 11 and power amplifier 12 by switch circuit 51.

According to this, radio frequency signals can be amplified by using two power amplifiers 11 and 12, and thus maximum output powers that power amplifiers 11 and 12 are to have in the first power class can be decreased.

### Embodiment 10

Next, Embodiment 10 is to be described. The present embodiment is different from Embodiments 6 and 9 above mainly in that a Wilkinson amplifier circuit is used as a power amplifier circuit and operation of one of the two power amplifiers is halted in the second power class. In the following, the present embodiment is to be described with reference to the drawings, focusing on different points from Embodiments 6 and 9 above.

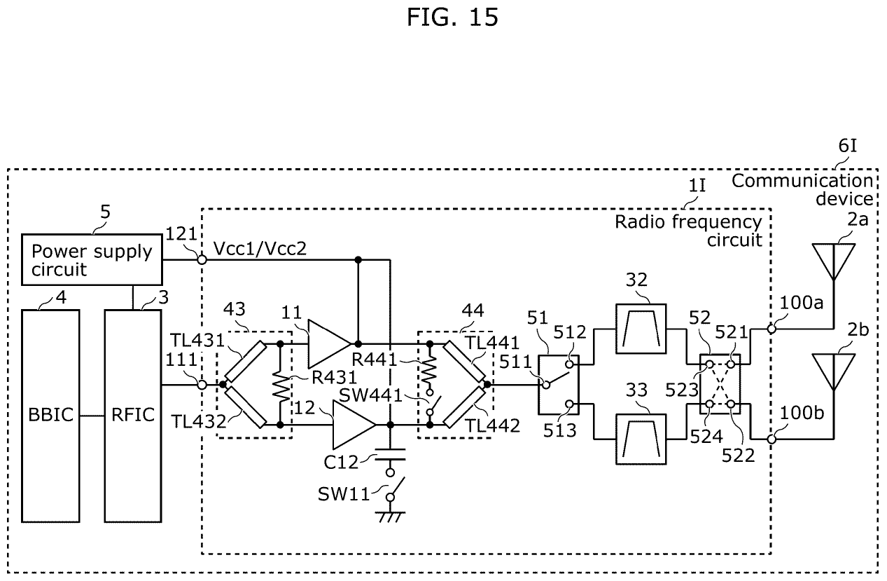

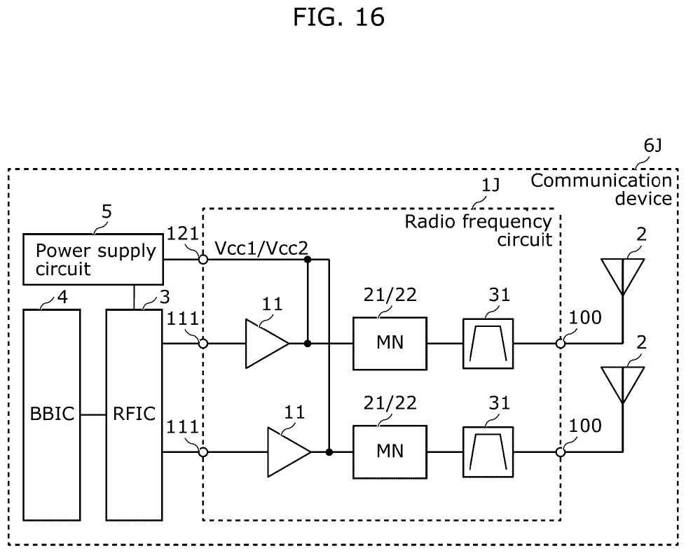

A circuit configuration of communication device 6I and radio frequency circuit 1I according to the present embodiment is to be described with reference to FIG. 15. FIG. 15 illustrates a circuit configuration of communication device 6I according to the present embodiment.

Note that FIG. 15 illustrates an exemplary circuit configuration, and communication device 6I and radio frequency circuit 1I may be implemented using any of various types of circuit implementations and circuit technologies. Thus, the description of communication device 6I and radio frequency circuit 1I provided below should not be interpreted in a limited manner.

Communication device 6I is the same as communication device 6E, except that radio frequency circuit 1I is included instead of radio frequency circuit 1E, and thus a description thereof is omitted.

Radio frequency circuit 1I includes power amplifiers 11 and 12, filters 32 and 33, Wilkinson divider 43, Wilkinson coupler 44D, switch circuits 51 and 52, capacitor C12, switch SW11, antenna connection terminals 100a and 100b, input terminal 111, and power supply voltage terminal 121. Note that radio frequency circuit 1I corresponds to a combination of the radio frequency circuits according to Embodiments 5 and 6 above, and thus a detailed description thereof is omitted.

As described above, radio frequency circuit 1I according to the present embodiment is radio frequency circuit 1I configured to support a first power class and a second power class whose maximum output power is lower than a maximum output power of the first power class, radio frequency circuit 1I including: power amplifier 11; filter 32; filter 33; and switch circuit 51 that includes terminal 511 connected to an output end of power amplifier 11, terminal 512 connected to filter 32, and terminal 513 connected to filter 33. Under a condition that the first power class is applied, power supply voltage Vcc1 is supplied to power amplifier 11, and filter 32 is connected to power amplifier 11 by switch circuit 51. Under a condition that the second power class is applied, power supply voltage Vcc2 is supplied to power amplifier 11, and filter 33 is connected to power amplifier 11 by switch circuit 51. Power supply voltage Vcc1 is higher than power supply voltage Vcc2, and an input impedance of filter 32 is lower than an input impedance of filter 33.

According to this, connection of power amplifier 12 can be switched between filters 32 and 33 having different input impedances according to which of the first power class or the second power class is applied, and thus the load impedance viewed from power amplifier 11 can be changed. Thus, both a power supply voltage and a load impedance are adjusted according to which of the first power class or the second power class is applied, and thus power amplifier 11 can support both the first power class and the second power class. In particular, under a condition that the power supply voltage is fixed in a case where the maximum output power of the first power class and the maximum output power of the second power class have a great difference, a range for adjusting the load impedance is increased, and a switching loss is increased in the case of a low load impedance. Thus, the range for adjusting the load impedance can be prevented from increasing and the switching loss can be reduced, by adjusting both the power supply voltage and the load impedance. Under a condition that the load impedance is fixed in the case where the maximum output power of the first power class and the maximum output power of the second power class have a great difference, a higher power supply voltage is necessary and power amplifier 11 is required to have higher voltage durability. Thus, voltage durability that power amplifier 11 is to have can be decreased by adjusting both the power supply voltage and the load impedance.

For example, in radio frequency circuit 1I according to the present embodiment, power amplifier 11 may be further configured to support a third power class whose maximum output power is lower than the maximum output power of the first power class and is higher than the maximum output power of the second power class, and under a condition that the third power class is applied, power supply voltage Vcc2 may be supplied to power amplifier 11, and filter 32 may be connected to power amplifier 11 by switch circuit 51.

According to this, in the third power class between the first power class and the second power class, the same power supply voltage as in the second power class is supplied, and filter 32 the same as in the first power class can be connected to power amplifier 11. Thus, power efficiency can be improved by reducing an increase in power supply voltage in the third power class.

For example, radio frequency circuit 1I according to the present embodiment may further include: power amplifier 12; transfer line TL441 connected between the output end of power amplifier 11 and terminal 511 of switch circuit 51; transfer line TL442 connected between an output end of power amplifier 12 and terminal 511 of switch circuit 51; and resistor R441 connected in parallel to transfer line TL441 and transfer line TL442, between the output end of power amplifier 11 and the output end of power amplifier 12. Under the condition that the first power class is applied, power supply voltage Vcc1 may be supplied to power amplifier 11 and power amplifier 12, and filter 32 may be connected to power amplifier 11 and power amplifier 12 by switch circuit 51, and under the condition that the second power class is applied, power supply voltage Vcc2 may be supplied to power amplifier 11, filter 33 may be connected to power amplifier 11 by switch circuit 51, and operation of power amplifier 12 may be halted.

According to this, radio frequency signals can be amplified by using two power amplifiers 11 and 12, and thus maximum output powers that power amplifiers 11 and 12 are to have in the first power class can be decreased. Furthermore, the operation of power amplifier 12 can be halted in the second power class with a lower maximum output power, and thus power efficiency in the second power class can be prevented from decreasing.

Table 2 shows specific examples of combinations of passbands or supported bands of filters 32 and 33 and power classes, which can be used in Embodiments 7 to 10 above.

TABLE 2

| | Passband or | First | Second | Third |
|---|---|---|---|---|
| | supported band | power class | power class | power class |
| #1 | 6425-7125 MHz | PC1/PC1.5/PC2 | PC5 | PC3 |
| #2 | n104 | PC1/PC1.5/PC2 | PC5 | PC3 |

### Other Embodiments

The above has described radio frequency circuits according to the present disclosure, based on the embodiments, yet the radio frequency circuits according to the present disclosure are not limited to the above embodiments. The present disclosure also encompasses another embodiment achieved by combining arbitrary elements in the above embodiments, variations resulting from applying, to the embodiments, various modifications that may be conceived by those skilled in the art within a range that does not depart from the scope of the present disclosure, and various devices that each include any of the radio frequency circuits.

For example, in the circuit configurations of the radio frequency circuits according to the above embodiments, another circuit element and a line, for instance, may be provided between circuit elements and paths connecting signal paths, which are disclosed in the drawings. An inductor and/or a capacitor may be provided between a power supply voltage terminal and a power amplifier, for example.

The communication device according to each of the above embodiments may include a plurality of radio frequency circuits. In this case, the plurality of radio frequency circuits may be combined into one radio frequency circuit. An example of such a radio frequency circuit is to be described with reference to FIG. 16. FIG. 16 illustrates a circuit configuration of communication device 6J according to another embodiment. Communication device 6J includes radio frequency circuit 1J, two antennas 2, RFIC 3, BBIC 4, and power supply circuit 5. Radio frequency circuit 1J includes two power amplifiers 11, two variable load matching circuits 21 or 22, two filters 31, two antenna connection terminals 100, two input terminals 111, and power supply voltage terminal 121.

The following states features of the radio frequency circuits described based on the above embodiments.

<1> A radio frequency circuit configured to support a first power class and a second power class whose maximum output power is lower than a maximum output power of the first power class, the radio frequency circuit including:
a first power amplifier; and
a variable load matching circuit connected to an output end of the first power amplifier,
wherein under a condition that the first power class is applied, a first power supply voltage is supplied to the first power amplifier, and a load impedance viewed from the first power amplifier is adjusted to a first impedance by the variable load matching circuit,
under a condition that the second power class is applied, a second power supply voltage is supplied to the first power amplifier, and the load impedance viewed from the first power amplifier is adjusted to a second impedance by the variable load matching circuit,
the first power supply voltage is higher than the second power supply voltage, and
the first impedance is lower than the second impedance.

<2> The radio frequency circuit according to <1>,
wherein the first power amplifier is further configured to support a third power class whose maximum output power is lower than the maximum output power of the first power class and is higher than the maximum output power of the second power class, and
under a condition that the third power class is applied, the second power supply voltage is supplied to the first power amplifier, and the load impedance viewed from the first power amplifier is adjusted to the first impedance by the variable load matching circuit.

<3> The radio frequency circuit according to <1> or <2>,
wherein the variable load matching circuit includes:
   a first capacitor and a first switch connected in series between the first power amplifier and an antenna connection terminal; and
   a second capacitor and a second switch connected in parallel to the first capacitor and the first switch, between the first power amplifier and the antenna connection terminal, the second capacitor and the second switch being connected in series,
a capacitance of the first capacitor is greater than a capacitance of the second capacitor,
under the condition that the first power class is applied, the first switch is closed, and the second switch is open, and
under the condition that the second power class is applied, the first switch is open, and the second switch is closed.

<4> The radio frequency circuit according to <1> or <2>,
wherein the variable load matching circuit includes:
   a first inductor connected between the first power amplifier and an antenna connection terminal;
   a second inductor and a first switch connected in parallel to the first inductor, between the first power amplifier and the antenna connection terminal, the second inductor and the first switch being connected in series;
   a first capacitor connected between ground and a path between the first power amplifier and the antenna connection terminal; and
   a second capacitor and a second switch connected in parallel to the first capacitor, between the ground and the path between the first power amplifier and the antenna connection terminal, the second capacitor and the second switch being connected in series,
under the condition that the first power class is applied, the first switch is open, and the second switch is closed, and
under the condition that the second power class is applied, the first switch is closed, and the second switch is open.

<5> The radio frequency circuit according to any one of <1> to <4>, further including:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the variable load matching circuit,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier and the second power amplifier, and the load impedance viewed from the first power amplifier and the second power amplifier is adjusted to the second impedance by the variable load matching circuit.

<6> The radio frequency circuit according to <1> or <2>, further including:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the variable load matching circuit,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier, the load impedance viewed from the first power amplifier is adjusted to the second impedance by the variable load matching circuit, and operation of the second power amplifier is halted.

<7> The radio frequency circuit according to <6>,
wherein the variable load matching circuit includes:
   a first inductor connected between the secondary coil and an antenna connection terminal;
   a second inductor and a first switch connected in parallel to the first inductor, between the secondary coil and the antenna connection terminal, the second inductor and the first switch being connected in series;
   a first capacitor and a second capacitor connected in series between ground and a path between the first power amplifier and the antenna connection terminal; and
   a second switch connected between the ground and a path between the first capacitor and the second capacitor,
the radio frequency circuit further includes a third capacitor and a third switch connected in series between the ground and a path between the second power amplifier and the primary coil,
under the condition that the first power class is applied, the first switch and the third switch are open, and the second switch is closed, and
under the condition that the second power class is applied, the first switch and the third switch are closed, and the second switch is open.

<8> The radio frequency circuit according to any one of <1> to <4>, further including:
a second power amplifier;
a first transfer line connected between the output end of the first power amplifier and the variable load matching circuit;
a second transfer line connected between an output end of the second power amplifier and the variable load matching circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier and the second power amplifier, and the load impedance viewed from the first power amplifier and the second power amplifier is adjusted to the second impedance by the variable load matching circuit.

<9> The radio frequency circuit according to any one of <1> to <4>, further including:
a second power amplifier;
a first transfer line connected between the output end of the first power amplifier and the variable load matching circuit;
a second transfer line connected between an output end of the second power amplifier and the variable load matching circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier, the load impedance viewed from the first power amplifier is adjusted to the second impedance by the variable load matching circuit, and operation of the second power amplifier is halted.

<10> The radio frequency circuit according to <9>, further including:
a third capacitor and a third switch connected in series between ground and a path between the second power amplifier and the second transfer line; and
a fourth switch connected in series to the resistor, between the output end of the first power amplifier and the output end of the second power amplifier,
wherein under the condition that the first power class is applied, the third switch is open, and the fourth switch is closed, and
under the condition that the second power class is applied, the third switch is closed, and the fourth switch is open.

<11> A radio frequency circuit configured to support a first power class and a second power class whose maximum output power is lower than a maximum output power of the first power class, the radio frequency circuit including:
a first power amplifier;
a first filter;
a second filter; and
a switch circuit that includes a first terminal connected to an output end of the first power amplifier, a second terminal connected to the first filter, and a third terminal connected to the second filter,
wherein under a condition that the first power class is applied, a first power supply voltage is supplied to the first power amplifier, and the first filter is connected to the first power amplifier by the switch circuit,
under a condition that the second power class is applied, a second power supply voltage is supplied to the first power amplifier, and the second filter is connected to the first power amplifier by the switch circuit,
the first power supply voltage is higher than the second power supply voltage, and
an input impedance of the first filter is lower than an input impedance of the second filter.

<12> The radio frequency circuit according to <11>,
wherein the first power amplifier is further configured to support a third power class whose maximum output power is lower than the maximum output power of the first power class and is higher than the maximum output power of the second power class, and
under a condition that the third power class is applied, the second power supply voltage is supplied to the first power amplifier, and the first filter is connected to the first power amplifier by the switch circuit.

<13> The radio frequency circuit according to <11> or <12>, further including:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the first terminal of the switch circuit,
wherein under the condition that the first power class is applied, the first power supply voltage is supplied to the first power amplifier and the second power amplifier, and the first filter is connected to the transformer by the switch circuit, and
under the condition that the second power class is applied, the second power supply voltage is supplied to the first power amplifier and the second power amplifier, and the second filter is connected to the transformer by the switch circuit.

<14> The radio frequency circuit according to <11> or <12>, further including:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the first terminal of the switch circuit,
wherein under the condition that the first power class is applied, the first power supply voltage is supplied to the first power amplifier and the second power amplifier, and the first filter is connected to the transformer by the switch circuit, and
under the condition that the second power class is applied, the second power supply voltage is supplied to the first power amplifier, the second filter is connected to the transformer by the switch circuit, and operation of the second power amplifier is halted.

5<15> The radio frequency circuit according to <11> or <12>, further including:
a second power amplifier;
a first transfer line connected between the output end of the first power amplifier and the first terminal of the switch circuit;
a second transfer line connected between an output end of the second power amplifier and the first terminal of the switch circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and the first filter is connected to the first power amplifier and the second power amplifier by the switch circuit, and
under the condition that the second power class is applied, the second power supply voltage is supplied to the first power amplifier and the second power amplifier, and the second filter is connected to the first power amplifier and the second power amplifier by the switch circuit.

<16> The radio frequency circuit according to <11> or <12>, further including:
a second power amplifier;
a first transfer line connected between the output end of the first power amplifier and the first terminal of the switch circuit;
a second transfer line connected between an output end of the second power amplifier and the first terminal of the switch circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and the first filter is connected to the first power amplifier and the second power amplifier by the switch circuit, and
under the condition that the second power class is applied, the second power supply voltage is supplied to the first power amplifier, the second filter is connected to the first power amplifier by the switch circuit, and operation of the second power amplifier is halted.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to communication devices such as mobile phones, as radio frequency circuits disposed in front end portions.

1. A radio frequency circuit configured to support a first power class and a second power class whose maximum output power is lower than a maximum output power of the first power class, the radio frequency circuit comprising:
a first power amplifier; and
a variable load matching circuit connected to an output end of the first power amplifier,
wherein under a condition that the first power class is applied, a first power supply voltage is supplied to the first power amplifier, and a load impedance viewed from the first power amplifier is adjusted to a first impedance by the variable load matching circuit,
under a condition that the second power class is applied, a second power supply voltage is supplied to the first power amplifier, and the load impedance viewed from the first power amplifier is adjusted to a second impedance by the variable load matching circuit,
the first power supply voltage is higher than the second power supply voltage, and
the first impedance is lower than the second impedance.

2. The radio frequency circuit according to claim 1,
wherein the first power amplifier is further configured to support a third power class whose maximum output power is lower than the maximum output power of the first power class and is higher than the maximum output power of the second power class, and
under a condition that the third power class is applied, the second power supply voltage is supplied to the first power amplifier, and the load impedance viewed from the first power amplifier is adjusted to the first impedance by the variable load matching circuit.

3. The radio frequency circuit according to claim 1,
wherein the variable load matching circuit includes:
a first capacitor and a first switch connected in series between the first power amplifier and an antenna connection terminal; and
a second capacitor and a second switch connected in parallel to the first capacitor and the first switch, between the first power amplifier and the antenna connection terminal, the second capacitor and the second switch being connected in series,
a capacitance of the first capacitor is greater than a capacitance of the second capacitor,
under the condition that the first power class is applied, the first switch is closed, and the second switch is open, and
under the condition that the second power class is applied, the first switch is open, and the second switch is closed.

4. The radio frequency circuit according to claim 1,
wherein the variable load matching circuit includes:
a first inductor connected between the first power amplifier and an antenna connection terminal;
a second inductor and a first switch connected in parallel to the first inductor, between the first power amplifier and the antenna connection terminal, the second inductor and the first switch being connected in series;
a first capacitor connected between ground and a path between the first power amplifier and the antenna connection terminal; and
a second capacitor and a second switch connected in parallel to the first capacitor, between the ground and the path between the first power amplifier and the antenna connection terminal, the second capacitor and the second switch being connected in series,
under the condition that the first power class is applied, the first switch is open, and the second switch is closed, and
under the condition that the second power class is applied, the first switch is closed, and the second switch is open.

5. The radio frequency circuit according to claim 1, further comprising:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the variable load matching circuit,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier and the second power amplifier, and the load impedance viewed from the first power amplifier and the second power amplifier is adjusted to the second impedance by the variable load matching circuit.

6. The radio frequency circuit according to claim 1, further comprising:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the variable load matching circuit,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier, the load impedance viewed from the first power amplifier is adjusted to the second impedance by the variable load matching circuit, and operation of the second power amplifier is halted.

7. The radio frequency circuit according to claim 6,
wherein the variable load matching circuit includes:
a first inductor connected between the secondary coil and an antenna connection terminal;
a second inductor and a first switch connected in parallel to the first inductor, between the secondary coil and the antenna connection terminal, the second inductor and the first switch being connected in series;
a first capacitor and a second capacitor connected in series between ground and a path between the first power amplifier and the antenna connection terminal; and
a second switch connected between the ground and a path between the first capacitor and the second capacitor,
the radio frequency circuit further comprises a third capacitor and a third switch connected in series between the ground and a path between the second power amplifier and the primary coil,
under the condition that the first power class is applied, the first switch and the third switch are open, and the second switch is closed, and
under the condition that the second power class is applied, the first switch and the third switch are closed, and the second switch is open.

8. The radio frequency circuit according to claim 1, further comprising:
a second power amplifier;
a first transfer line connected between the output end of the first power amplifier and the variable load matching circuit;
a second transfer line connected between an output end of the second power amplifier and the variable load matching circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier and the second power amplifier, and the load impedance viewed from the first power amplifier and the second power amplifier is adjusted to the second impedance by the variable load matching circuit.

9. The radio frequency circuit according to claim 1, further comprising:
a second power amplifier;
a first transfer line connected between the output end of the first power amplifier and the variable load matching circuit;
a second transfer line connected between an output end of the second power amplifier and the variable load matching circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and a load impedance viewed from the first power amplifier and the second power amplifier is adjusted to the first impedance by the variable load matching circuit, and
under the condition that the second power class is applied, the second power supply voltage is supplied to the first power amplifier, the load impedance viewed from the first power amplifier is adjusted to the second impedance by the variable load matching circuit, and operation of the second power amplifier is halted.

10. The radio frequency circuit according to claim 9, further comprising:
a third capacitor and a third switch connected in series between ground and a path between the second power amplifier and the second transfer line; and
a fourth switch connected in series to the resistor, between the output end of the first power amplifier and the output end of the second power amplifier,
wherein under the condition that the first power class is applied, the third switch is open, and the fourth switch is closed, and
under the condition that the second power class is applied, the third switch is closed, and the fourth switch is open.

11. A radio frequency circuit configured to support a first power class and a second power class whose maximum output power is lower than a maximum output power of the first power class, the radio frequency circuit comprising:
a first power amplifier;
a first filter;
a second filter; and
a switch circuit that includes a first terminal connected to an output end of the first power amplifier, a second terminal connected to the first filter, and a third terminal connected to the second filter,
wherein under a condition that the first power class is applied, a first power supply voltage is supplied to the first power amplifier, and the first filter is connected to the first power amplifier by the switch circuit,
under a condition that the second power class is applied, a second power supply voltage is supplied to the first power amplifier, and the second filter is connected to the first power amplifier by the switch circuit,
the first power supply voltage is higher than the second power supply voltage, and
an input impedance of the first filter is lower than an input impedance of the second filter.

12. The radio frequency circuit according to claim 11,
wherein the first power amplifier is further configured to support a third power class whose maximum output power is lower than the maximum output power of the first power class and is higher than the maximum output power of the second power class, and
under a condition that the third power class is applied, the second power supply voltage is supplied to the first power amplifier, and the first filter is connected to the first power amplifier by the switch circuit.

13. The radio frequency circuit according to claim 11, further comprising:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the first terminal of the switch circuit,
wherein under the condition that the first power class is applied, the first power supply voltage is supplied to the first power amplifier and the second power amplifier, and the first filter is connected to the transformer by the switch circuit, and
under the condition that the second power class is applied, the second power supply voltage is supplied to the first power amplifier and the second power amplifier, and the second filter is connected to the transformer by the switch circuit.

14. The radio frequency circuit according to claim 11, further comprising:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the first terminal of the switch circuit,
wherein under the condition that the first power class is applied, the first power supply voltage is supplied to the first power amplifier and the second power amplifier, and the first filter is connected to the transformer by the switch circuit, and
under the condition that the second power class is applied, the second power supply voltage is supplied to the first power amplifier, the second filter is connected to the transformer by the switch circuit, and operation of the second power amplifier is halted.

15. The radio frequency circuit according to claim 11, further comprising:
a second power amplifier;
a first transfer line connected between the output end of the first power amplifier and the first terminal of the switch circuit;
a second transfer line connected between an output end of the second power amplifier and the first terminal of the switch circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and the first filter is connected to the first power amplifier and the second power amplifier by the switch circuit, and
under the condition that the second power class is applied, the second power supply voltage is supplied to the first power amplifier and the second power amplifier, and the second filter is connected to the first power amplifier and the second power amplifier by the switch circuit.

16. The radio frequency circuit according to claim 11, further comprising:
a second power amplifier;
a first transfer line connected between the output end of the first power amplifier and the first terminal of the switch circuit;
a second transfer line connected between an output end of the second power amplifier and the first terminal of the switch circuit; and
a resistor connected in parallel to the first transfer line and the second transfer line, between the output end of the first power amplifier and the output end of the second power amplifier,
wherein under the condition that the first power class is applied, the first power supply voltage is supplied to the first power amplifier and the second power amplifier, and the first filter is connected to the first power amplifier and the second power amplifier by the switch circuit, and
under the condition that the second power class is applied, the second power supply voltage is supplied to the first power amplifier, the second filter is connected to the first power amplifier by the switch circuit, and operation of the second power amplifier is halted.

17. The radio frequency circuit according to claim 1,
wherein the first power amplifier is further configured to support a third power class whose maximum output power is lower than the maximum output power of the first power class and is higher than the maximum output power of the second power class.

18. The radio frequency circuit according to claim 1,
wherein the variable load matching circuit includes:
a first inductor connected between the first power amplifier and an antenna connection terminal;
a second inductor and a first switch connected in parallel to the first inductor, between the first power amplifier and the antenna connection terminal, the second inductor and the first switch being connected in series;
a first capacitor connected between ground and a path between the first power amplifier and the antenna connection terminal; and
a second capacitor and a second switch connected in parallel to the first capacitor, between the ground and the path between the first power amplifier and the antenna connection terminal, the second capacitor and the second switch being connected in series.

19. The radio frequency circuit according to claim 11, further comprising:
a second power amplifier; and
a transformer that includes a primary coil and a secondary coil, the primary coil including two ends one of which is connected to the output end of the first power amplifier and a remaining one of which is connected to an output end of the second power amplifier, the secondary coil including an end connected to the first terminal of the switch circuit.

20. The radio frequency circuit according to claim 11, further comprising:
a second power amplifier;
a first transfer line connected between the output end of the first power amplifier and the first terminal of the switch circuit;
a second transfer line connected between an output end of the second power amplifier and the first terminal of the switch circuit; and
a resistor connected in parallel to the first transfer line and the second transfer line, between the output end of the first power amplifier and the output end of the second power amplifier.
